(19) United States
(12) Patent Application Publication
(10) Pub. No.: US 2013/0057785 A1
(43) Pub. Date: Mar. 7, 2013

(54) TELEVISION RECEIVER AND ELECTRONIC DEVICE

(71) Applicants: Shinji Hiratomo, Tokyo (JP); Tetsuo Okazaki, Tokyo (JP)

(72) Inventors: Shinji Hiratomo, Tokyo (JP); Tetsuo Okazaki, Tokyo (JP)

(73) Assignee: KABUSHIKI KAISHA TOSHIBA, Tokyo (JP)

(21) Appl. No.: 13/543,266

(22) Filed: Jul. 6, 2012

(30) Foreign Application Priority Data
Sep. 1, 2011 (JP) 2011-191128

(51) Int. Cl. H04N 5/64; H05K 7/00

(52) U.S. Cl. 348/843; 361/679.01; 348/E05.128

(57) ABSTRACT

According to one embodiment, an electronic device includes: an electronic component; a first member configured to cover at least a part of the electronic component; a second member positioned at a first side of the electronic component opposite a second side of the electronic component at which the first member is disposed; and a third member positioned between the second member and the electronic component, the third member being configured to support the electronic component and comprising a first end portion covered by a component that is partially exposed and a second end portion covered by at least one of the first member and the second member.

### CROSS-REFERENCE TO RELATED APPLICATIONS

This application is based upon and claims the benefit of priority from Japanese Patent Application No. 2011-191128, filed on Sep. 1, 2011, the entire contents of which are incorporated herein by reference.

### FIELD

Embodiments described herein relate generally to a television receiver and an electronic device.

### BACKGROUND

Conventionally known is an electronic device having a keyboard and a battery arranged side by side along a surface of a housing.

Desired in electronic devices such as television receivers is a structure having less inconvenience caused by arranging an electronic component such as a display device and modules or components such as a battery within a housing.

### BRIEF DESCRIPTION OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary perspective view illustrating a television receiver according to an embodiment;

FIG. 2 is an exemplary front view illustrating the television receiver in the embodiment;

FIG. 3 is an exemplary rear view illustrating the television receiver in the embodiment;

FIG. 4 is an exemplary side view illustrating the television receiver in the embodiment;

FIG. 5 is an exemplary side view illustrating the television receiver in the embodiment seen from a direction different from that in FIG. 4;

FIG. 6 is an exemplary side view illustrating the television receiver in the embodiment seen from a direction different from those in FIGS. 4 and 5;

FIG. 7 is an exemplary side view illustrating the television receiver in the embodiment seen from a direction different from those in FIGS. 4 to 6;

FIG. 8 is an exemplary exploded perspective view illustrating the television receiver in the embodiment;

FIG. 9 is an exemplary plan view illustrating an internal structure of the television receiver in the embodiment;

FIG. 10 is an exemplary sectional view across X-X illustrated in FIG. 2;

FIG. 11 is an exemplary perspective view illustrating a state in which the television receiver in the embodiment is held by a docking station;

FIG. 12 is an exemplary side view illustrating the state in which the television receiver in the embodiment is held by the docking station;

FIG. 13 is an exemplary perspective view illustrating a first member of the television receiver in the embodiment;

FIG. 14 is an exemplary perspective view illustrating a second member of the television receiver in the embodiment;

FIG. 15 is an exemplary perspective view illustrating a third member of the television receiver in the embodiment;

FIG. 16 is an exemplary perspective view illustrating a housing of the television receiver in the embodiment when a battery is removed;

FIG. 17 is an exemplary perspective view illustrating the housing of the television receiver in the embodiment seen from another angle when the battery is removed;

FIG. 18 is an exemplary perspective view illustrating the battery removed from the housing of the television receiver in the embodiment when the battery is removed;

FIG. 19 is an exemplary perspective view illustrating the battery removed from the housing of the television receiver in the embodiment seen from another angle when the battery is removed;

FIG. 20 is an exemplary perspective view illustrating a part of the housing of the television receiver in the embodiment when the battery is removed;

FIG. 21 is an exemplary perspective view illustrating the part of the housing of the television receiver in the embodiment seen from another angle when the battery is removed;

FIG. 22 is an exemplary sectional view across XXII-XXII illustrated in FIG. 20;

FIG. 23 is an exemplary perspective view illustrating a part of the first member of the television receiver in the embodiment;

FIG. 24 is an exemplary perspective view illustrating a part of the second member of the television receiver in the embodiment;

FIG. 25 is an exemplary perspective view illustrating the second member and the third member of the television receiver in the embodiment;

FIG. 26 is an exemplary perspective view illustrating a display device of the television receiver in the embodiment seen from a rear surface;

FIG. 27 is an exemplary sectional view across XXVII-XXVII illustrated in FIG. 2;

FIG. 28 is an exemplary perspective view illustrating a part of the second member and the third member of the television receiver in the embodiment;

FIG. 29 is an exemplary sectional view across XXIX-XXIX illustrated in FIG. 2; and

FIG. 30 is an exemplary perspective view illustrating an electronic device according to a variation of the embodiment.

### DETAILED DESCRIPTION

In general, according to one embodiment, a television receiver comprises: a display device comprising a display screen; a first housing member configured to cover an edge of the display screen; a second housing member positioned at a first side of the display device opposite a second side of the display device at which the display screen is disposed, and to cover a rear surface of the display device; a third housing member positioned between the second housing member and the display device, the third housing member being configured to support the display device and comprising a side wall extending between the first housing member and the second housing member and an end portion, the end portion being located on an opposite side of the side wall and covered by at least one of the first housing member and the second housing member; a circuit board positioned between the second housing member and the display device; a connector electrically connected to the circuit board and exposed to an outside of the side wall of the third housing member; and a module attached to the third housing member at a position where the module covers the side wall, and electrically connected to the connector.

The same elements are comprised in exemplary embodiments described below. Therefore, in explanations below, the same reference numerals are assigned to the same elements, and redundant explanations thereof are omitted. In addition, in each of the drawings, directions (an X direction, a Y direction, and a Z direction) are illustrated for convenience. The X direction corresponds to the longitudinal direction of a display screen 4a of a television receiver 1 in a front view. The Y direction corresponds to the short side direction of the display screen 4a viewed from the front. The Z direction corresponds to the front-back direction of the display screen 4a (depth direction, the thickness direction of a housing 3) viewed from the front. The X direction, the Y direction, and the Z direction perpendicularly cross each other.

In the embodiments described below, explained as an example is an electronic device configured as a television receiver. However, the electronic device according to the embodiments is not limited thereto. For example, the electronic device according to the embodiment may be various electronic devices such as a tablet personal computer, a slate personal computer, a smartphone, a smart television, a smart book, a cellular phone, a personal digital assistant (PDA), a video display device, and a video phone.

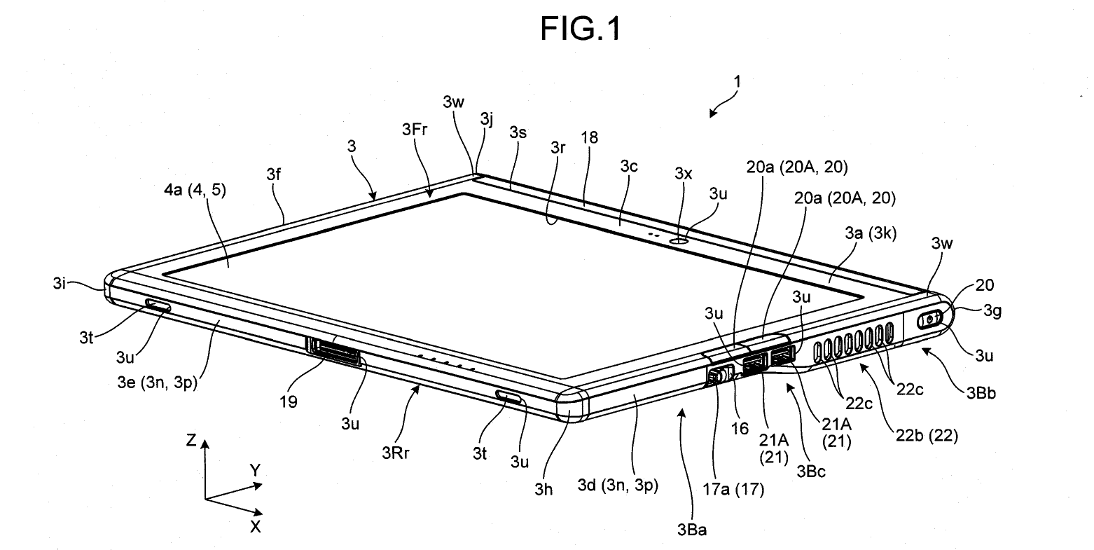

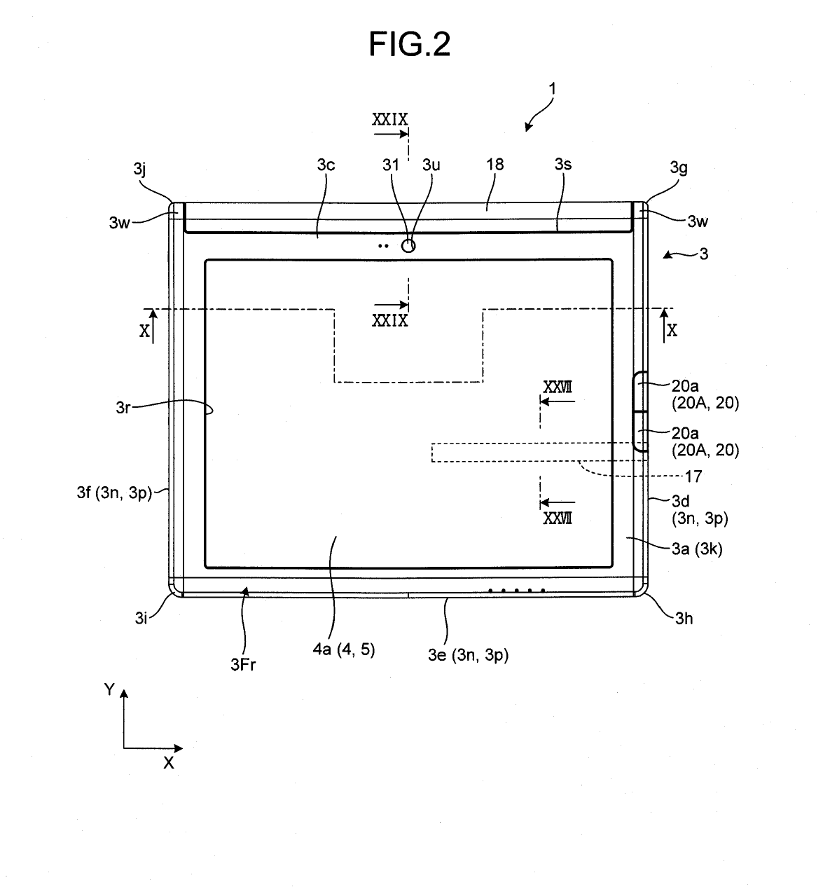

In the embodiment, as an example, as illustrated in FIGS. 1 to 7, the housing 3 of the television receiver 1, is configured in a rectangular shape (in the embodiment, an oblong shape, as an example) viewed from the front and viewed from the rear. In the embodiment, as an example, the housing 3 has a shape of a flat parallelepiped that is thin in the front-back direction as illustrated in FIGS. 2 and 5. The housing 3 comprises a front surface (frontal surface, face, first surface, first surface section) 3a and a rear surface (back surface, face, second surface, second surface section) 3b that is on the opposite side of the front surface 3a. The front surface 3a and the rear surface 3b are laid approximately in parallel. The housing 3 comprises four ends (side portions, edge portions) 3c to 3f and four corners (pointed portions, curved portions, ends) 3g to 3j viewed from the front, as illustrated in FIGS. 1, 4 to 7. The ends 3c and 3e are examples of longer sides. The ends 3d and 3f are examples of shorter sides.

The housing 3 also comprises a wall portion (first wall portion, first portion, plate, frame, front wall portion, frontal wall portion, top wall portion) 3k comprising the front surface 3a, and a wall portion (second wall portion, second portion, plate, rear wall portion, back wall portion, bottom wall portion) 3m comprising the rear surface 3b. Each of the wall portions 3k and 3m is in a rectangular shape (in the embodiment, an oblong shape, as an example). The housing 3 also comprises four wall portions (third wall portions, third parts, plates, side wall portions, end wall portions, standing wall portions, stretched portions) 3n laid across and between the wall portion 3k and the wall portion 3m comprising side surfaces (surface, circumferential surface, third surface) 3p. An opening 3r that is rectangular in shape is disposed on the wall portion 3k, as an example.

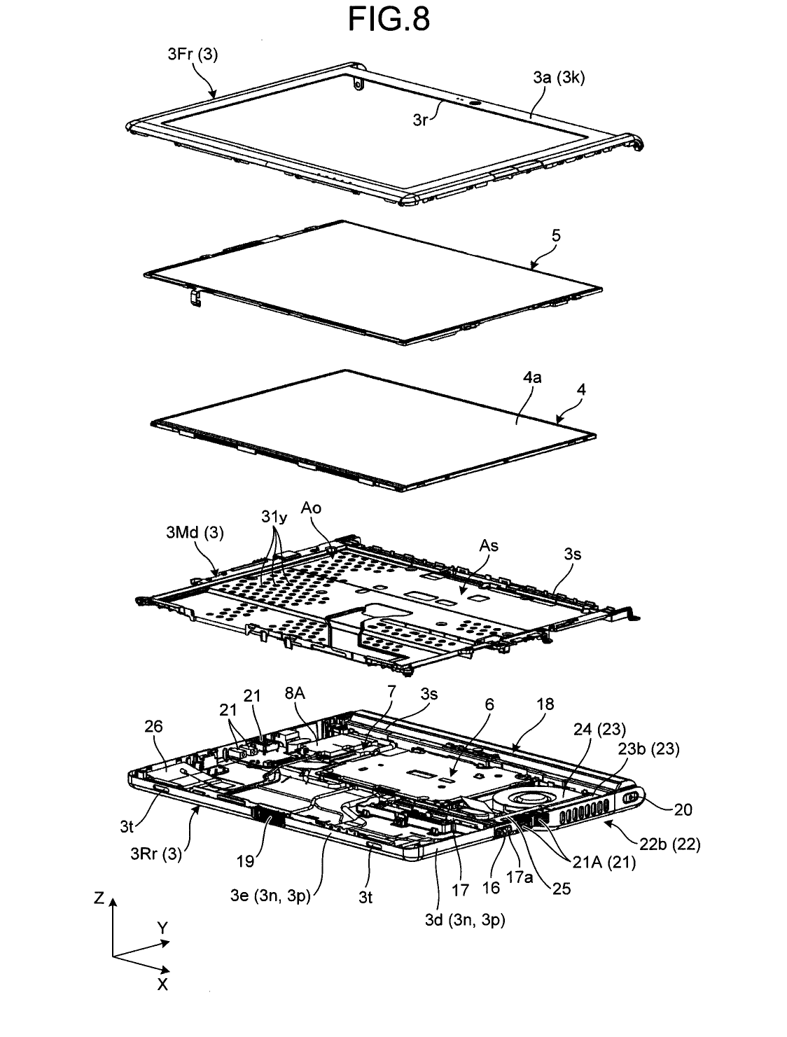

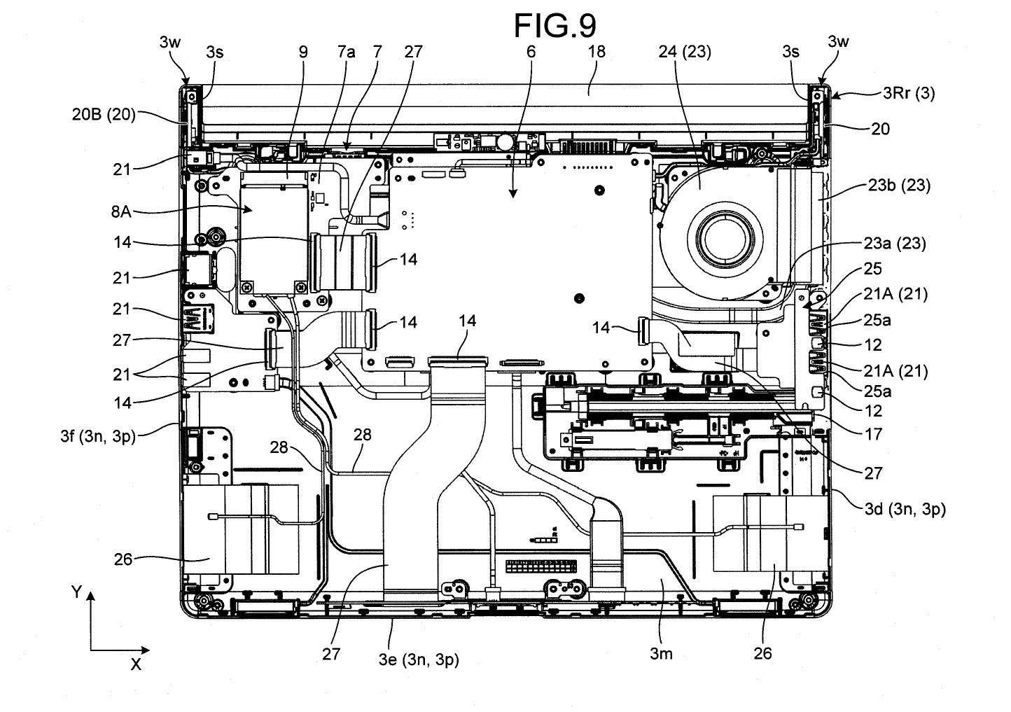

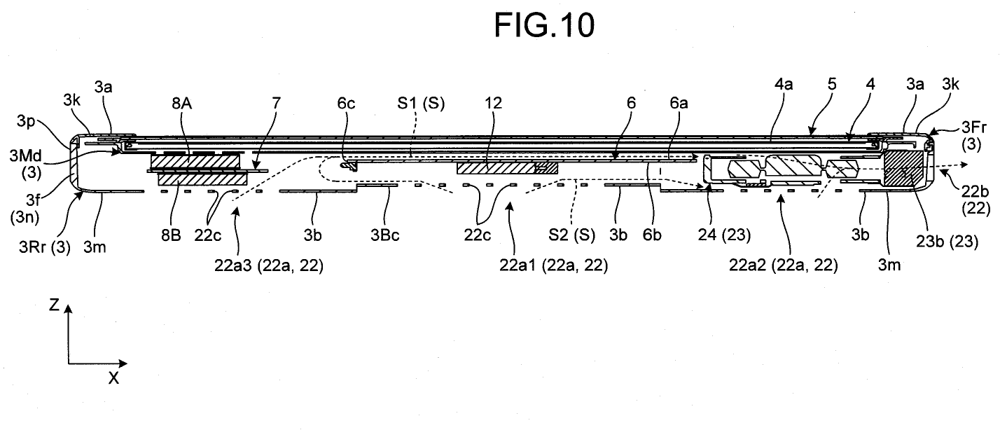

The housing 3 can be structured as a combination of a plurality of components (divided bodies). In the embodiment, as an example, the housing 3 comprises a first member (first portion, front side member, cover) 3Fr at least comprising the wall portion 3k, and a second member (second portion, rear side member, base, bottom) 3Rr at least comprising the wall portion 3m. Each of the wall portions 3n is comprised in at least one of the first member 3Fr and the second member 3Rr (for example, the second member 3Rr). In the embodiment, as illustrated in FIGS. 8 and 10, the housing 3 also comprises, in addition to the first member 3Fr and the second member 3Rr, a third member (third portion, intermediate member, isolating member, barrier member, wall portion member, interposed member, inner plate, middle plate, middle frame) 3Md placed between the first member 3Fr and the second member 3Rr. A part of the wall portions 3n can be comprised in the third member 3Md as well. The housing 3 can be made of a metallic material or a synthetic resin material, for example. As an example, the second member 3Rr and the third member 3Md may be made of a material of relatively high stiffness (for example, a metallic material such as magnesium alloy), and the first member 3Fr can be made of a material of relatively low stiffness (a material less stiffer than the second member 3Rr and the third member 3Md; a synthetic resin material, for example). The first member 3Fr, the second member 3Rr, and the third member 3Md can comprise wall portions (protruding portions, protruding wall portions) such as ribs. Such wall portions tend to increase the stiffness of the housing 3. The third member 3Md, as an example, can comprise openings such as through-holes. Such openings, as an example, enable the housing 3 to be more light-weighted.

In the embodiment, as an example, as illustrated in FIGS. 5 and 7, the thickness of a first section 3Ba coming to the bottom or coming to the front side (the side nearer to a user) in a use position in which the longitudinal direction is laid horizontally is smaller than the thickness of a second section 3Bb coming to the top or coming to the rear side (the side further away from the user) in the use position. Therefore, when the television receiver 1 is placed and used on a setting surface P such as a desk, the height of the front surface 3a of the housing 3 and the display screen 4a from the setting surface (horizontal surface) P increases from the front side (bottom) toward the rear side (top). Therefore, according to the embodiment, as an example, the display screen 4a is positioned at a so-called inclined position in view of a user located at the left side of the television receiver 1 in FIG. 5 (the right side in FIG. 7), and, for the user, the display screen 4a is easier to see, advantageously. The angle between the display screen 4a and the setting surface P (the obtuse angle side) in the configuration illustrated in FIGS. 5 and 7 is preferably equal to or more than 135 degrees and less than 180 degrees. In the embodiment, as an example, a plurality of protrusions 3v (3v, 3v) are formed on the rear surface 3b of the housing 3. As it may be understood from FIGS. 5 and 7, the distance between the display screen 4a and the tip of each of the protrusions 3v disposed on the second section 3Bb illustrated in FIGS. 5 and 7 is longer than the distance between the display screen 4a and the tip of each of the protrusions 3v disposed on the first section 3Ba illustrated in FIGS. 5 and 7. In the embodiment, the protrusions 3v (the tip of each of the protrusions 3v) at the left side of FIG. 5 (the right side of FIG. 7) are examples of a first contacting portion, and the protrusions 3v (the tip of each of the protrusions 3v) illustrated in the right side in FIG. 5 (the left side of FIG. 7) are examples of a second contacting portion.

The housing 3 also comprises a component receptacle 17 for holding a component 16 in a removable manner. In the embodiment, as an example, an opening 17a of the component receptacle 17 opens to the end 3d. The opening 17a is formed on the end 3d coming to the top in one of use positions and not coming to the bottom in a non-use position. Such an arrangement allows the opening 17a to come to the top in the use position. Therefore, as an example, the component 16 is better prevented from falling out of the component receptacle 17 by the action of the gravity. The component 16 is, specifically, a stylus, a stylus pen, or a pen, for example.

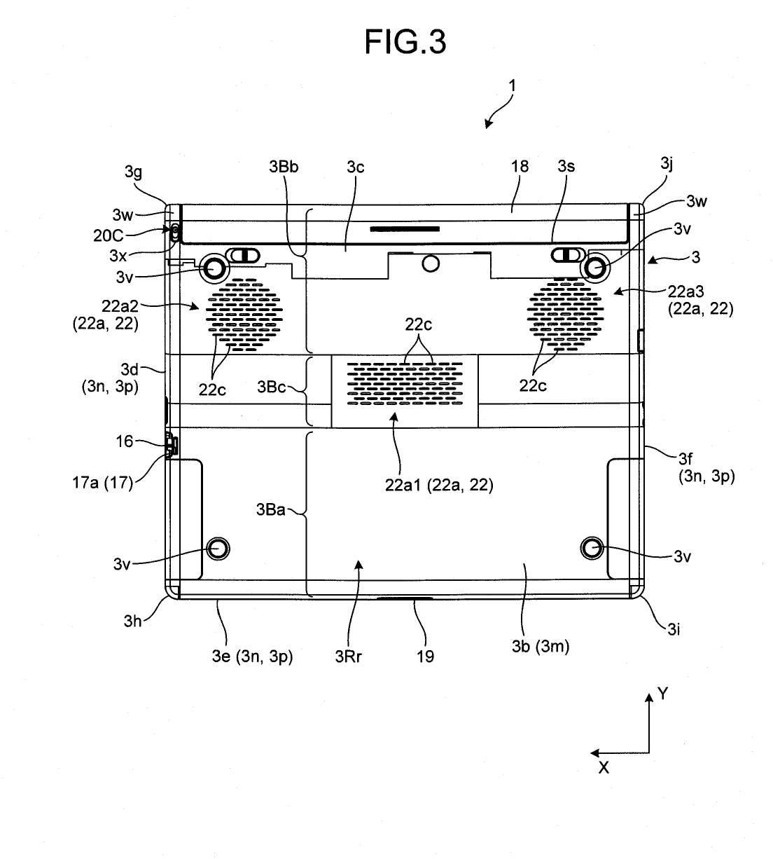

In the embodiment, as an example, as illustrated in FIGS. 2 and 3, a battery (module, component, electric component, removable component, replacement component) 18 and a display device 4 are not placed on top of each other in the thickness direction of the housing 3, but are arranged side by side along a direction in perpendicular to the thickness direction (the direction along the front surface 3a or the rear surface 3b, the X direction or the Y direction; along the Y direction in the embodiment, as an example). Therefore, as an example, the thickness of the housing 3 can be reduced compared with the configuration in which the battery 18 and the display device 4 are placed on top of each other in the thickness direction of the housing 3. Furthermore, as an example, the thickness of the battery 18 can be further increased easily compared with the configuration in which the battery 18 and the display device 4 are placed on top of each other in the thickness direction of the housing 3. Therefore, the per-volume capacity of the battery 18 can be increased easily. In the embodiment, the housing 3 comprises the first section 3Ba having a smaller thickness, and the second section 3Bb having a larger thickness, as illustrated in FIGS. 5 and 7. A battery receptacle (battery support) 3s for holding the battery 18 is laid along the end 3c of the second section 3Bb having a larger thickness. Therefore, as an example, the thickness of the battery 18 can be increased more easily compared with a configuration in which the battery receptacle is arranged in the first section 3Ba. Therefore, the per-volume storage capacity of the battery 18 can be increased easily.

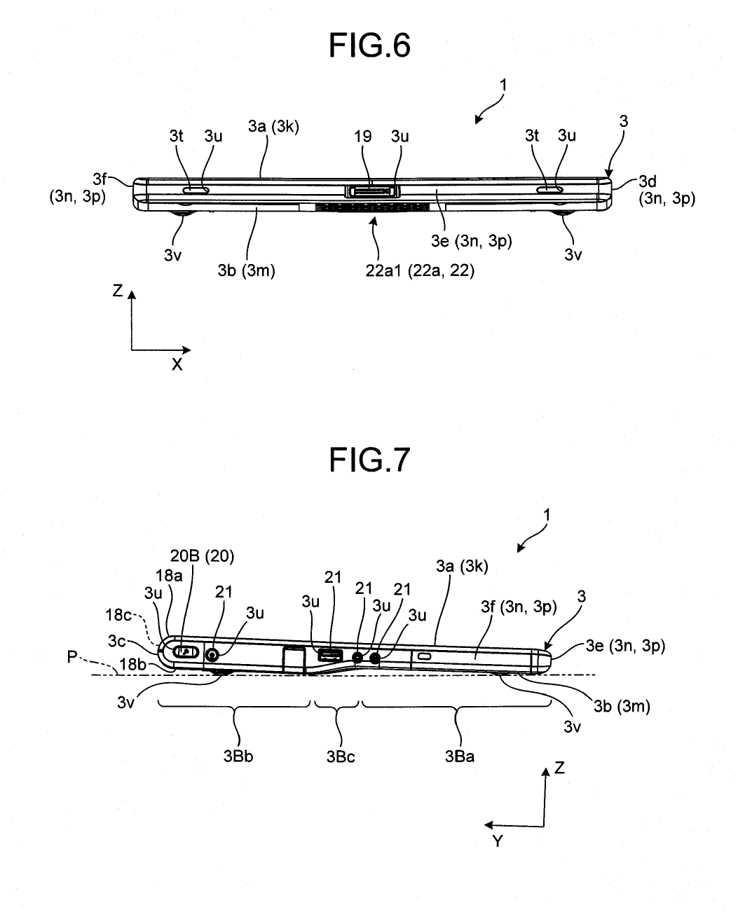

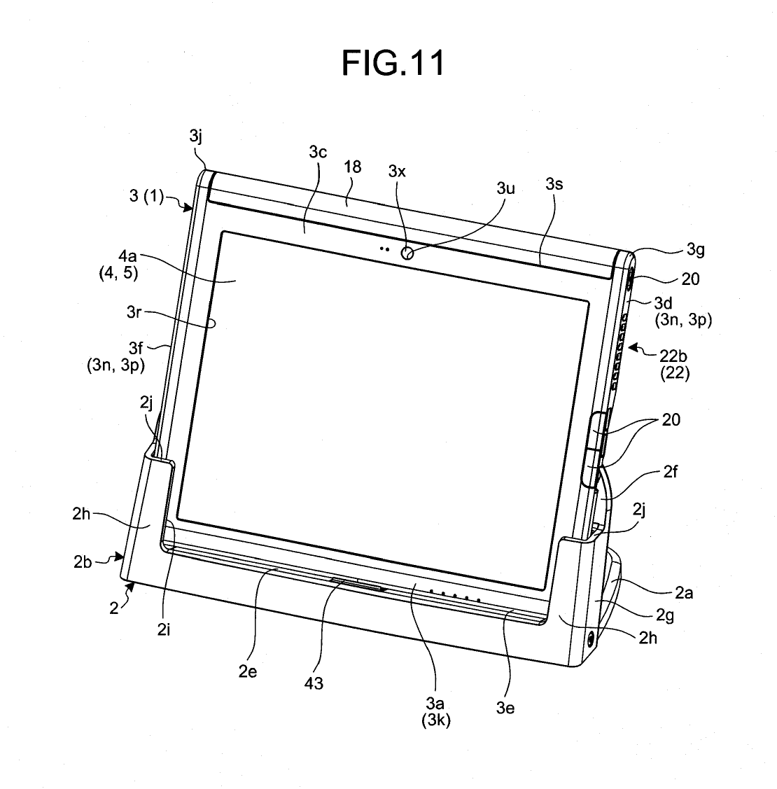

In the embodiment, as an example, as illustrated in FIG. 11, the end 3e located at the opposite side of the end 3c having the battery receptacle 3s is supported by a docking station 2. Therefore, as an example, an operator (e.g., a user) can attach or remove the battery 18 to or from the housing 3 while the television receiver 1 is supported by the docking station 2. Furthermore, a connector 19 to be connected to a connector (not illustrated) on the docking station 2 is arranged on the end 3e, as illustrated in FIGS. 3 and 6. Therefore, as an example, the battery receptacle 3s and the connector 19 can be comprised in the housing 3 easily without interrupting each other. A speaker cover 3t is also exposed from the end 3e. The connector 19 and the speaker cover 3t are respectively exposed through openings 3u that are formed on the wall portion 3n laid along the end 3e. The connector 19 is an example of a first connector.

Furthermore, in the embodiment, as an example, operating modules 20 and connectors 21 are provided on the front surface 3a or the side surface 3p of the housing 3, as illustrated in FIGS. 1 to 3, 5, and 7. The operating modules 20 can be a push button, a push switch, a sliding switch, or a pointing device, for example. The connectors 21 are a connector for a power cable, a universal serial bus (USB) connector, and a connector for a headset or a microphone, for example. The operating modules 20 and the connectors 21 are respectively exposed through the openings 3u that are provided on the wall portions 3k and 3n on the housing 3. Furthermore, a camera (camera module, imaging apparatus) 3x can be disposed on the front surface 3a.

Furthermore, in the embodiment, as an example, vent holes 22 through which the air for cooling electronic components 12 (see FIG. 10, for example) is collected and discharged are provided on the rear surface 3b and the side surface 3p of the housing 3 as illustrated in FIGS. 1, 3, 5, 6, and 10. In the embodiment, as an example, inlets 22a through which the air is collected are provided on the rear surface 3b (the wall portion 3m), and an outlet 22b through which the air is discharged is provided on the side surface 3p (the wall portion 3n, the end 3d). In the embodiment, each of the inlets 22a and the outlet 22b is formed as a collection of a plurality of small holes 22c provided on each of the wall portions 3m and 3n. Because the protruding portions 3v are provided on the rear surface 3b, even if the rear surface 3b is placed on the setting surface P as illustrated in FIGS. 5 and 7, the inlets 22a are not blocked. Furthermore, in the embodiment, a tilted section 3Bc is provided at a boundary area between the thin first section 3Ba and the thick second section 3Bb of the housing 3. An inlet 22a1 that is one of the inlets 22a is provided on the rear surface 3b of the tilted section 3Bc, as illustrated in FIG. 3. Because the distance between the tilted section 3Bc and the setting surface P is larger than the distance between other parts and the setting surface P, as illustrated in FIGS. 5 and 7, the flow resistance of the air at the inlet 22a1 provided on the tilted section 3Bc can be better reduced easily, and therefore, the cooling efficiency can further be increased easily. Furthermore, in the embodiment, because the inlet 22a is provided in plurality, even if any one of the inlets 22a is blocked for some reason, as an example, the air can be collected through the other inlets 22a into the housing 3. Therefore, the cooling performance is not lost easily. The housing 3 may be cooled by a cooling mechanism 23 (see FIGS. 9 and 10, for example), or may be naturally cooled (by convection cooling).

In the embodiment, as an example, the display device (display module, display, panel) 4 is housed between the first member 3Fr and the third member 3Md, as illustrated in FIGS. 8 and 10. The display screen 4a facing the front surface 3a of the display device 4 is exposed through the opening 3r to the front side (outside) of the housing 3. Therefore, a user can see the display screen 4a through the opening 3r from the front side. The display device 4 is in a rectangular shape (in the embodiment, an oblong shape, as an example) viewed from the front. Furthermore, the display device 4 is in a flat parallelepiped shape, being thin in the front-back direction. The display device 4 is a liquid crystal display (LCD) or an organic electro-luminescent display (GELD), for example.

Furthermore, in the embodiment, as an example, an input operation panel (touch panel, touch sensor, operation panel, as an example) 5 that is transparent, relatively thin, and rectangular in shape is provided on the front side (frontal side, the side of the wall portion 3k) of the display device 4. The input operation panel 5 covers the display screen 4a. An operator (e.g., a user) can perform an inputting process by performing an operation, such as touching, pressing, or rubbing, on the input operation panel 5 using a hand, a finger, the component 16 (stylus), and the like, or moving a hand, a finger, a stylus, and the like near the input operation panel 5. Furthermore, the light output from the display screen 4a of the display device 4 passes through the input operation panel 5, and is emitted toward the front side (outer side) of the housing 3 through the opening 3r on the wall portion 3k. The input operation panel 5 is an example of an input module.

In the embodiment, as an example, a plurality of boards 6, 7, and 25 are installed on the rear side of the display device (back side, behind side, the side near the wall portion 3m, the side opposite to the display screen 4a). In the embodiment, as an example, the boards 6, 7, and 25 are installed between the second member 3Rr and the third member 3Md in the housing 3, as illustrated in FIGS. 8 and 10. The boards 6, 7, and 25 are placed at positions different from each other, and are laid in parallel with the display device 4. Furthermore, the boards 6, 7, and 25 are provided in a manner separated from the wall portions 3k, 3m, and 3n, for example, that is, provided so that a space is formed between the boards and the wall portions 3k, 3m, and 3n, for example. The boards 6, 7, and 25 are provided side by side along the display device 4, so as not to be placed on top of each other in the thickness direction of the housing 3. The boards 6, 7, and 25 are also fixed to the housing 3 with couplers such as screws.

Furthermore, in the embodiment, as an example, the electronic components 12 provided in plurality (see FIG. 10; only partially illustrated in FIG. 10) such as a central processing unit (CPU), a graphic controller, a power circuit component, a platform controller hub (PCH), a memory slot connector, an LCD connector, an input/output (I/O) connector, a power coil, an element, a connector, and the like can be implemented on the board (first board, first circuit board, control board, main board) 6. The electronic components 12 comprise heating elements. The electronic component (heating element) 12 that generates a large amount of heat can have the cooling mechanism 23. The cooling mechanism 23 comprises a heat sink (heat receiving module, not illustrated), a heat pipe 23a, a heat dissipating module 23b, and a fan 24. The board 6 and the electronic components 12 make up at least a part of a controlling circuit (not illustrated). The controlling circuit can comprise a video signal processing circuit, a tuner, a high-definition multimedia interface (HDMI) signal processor, an audio video (AV) input terminal, a remote controller signal receiver, a controller, a selector, an on-screen display interface, a storage module (e.g., a read-only memory (ROM), a random access memory (RAM), a hard disk drive (HDD), and a solid state drive (SSD)), and a voice signal processing circuit. The controlling circuit controls video outputs (e.g., moving images or still images) from the display screen 4a of the display device 4, sound outputs from a speaker (not illustrated), and light emissions from a light emitting diode (LED) (not illustrated). The display device 4, the speaker, the LED, and the like are examples of an output module.

Furthermore, in the embodiment, as an example, as it may be understood from FIGS. 2, 5, 7, and 9, the boards 6 and 7, and the cooling mechanism 23 are disposed in the second section 3Bb having a larger thickness in the housing 3. Therefore, as an example, a larger space can be ensured compared with a structure in which the boards 6 and 7, and the cooling mechanism 23 are disposed in the first section 3Ba having a smaller thickness. Therefore, the cooling effect achieved by the air flow caused to flow by the fan 24 of the cooling mechanism 23 can be obtained easily. Furthermore, in the embodiment, as an example, the fan 24 and the heat dissipator 23b are disposed at the corner 3g where the end 3c and the end 3d meet and that come to the top in a specified (controlled) use position. Therefore, as an example, the fan 24 and the heat dissipator 23b can be positioned to the upper side of the housing 3 regardless of the use position of the television receiver 1. Therefore, as an example, less heat stays in the housing 3. The fan 24 and the heat dissipator 23b are provided at positions adjacent to the outlet 22b.

Furthermore, in the embodiment, as an example, the board 7 is disposed at a position interposing the board 6 with the cooling mechanism 23 (a position arranged in the order of the board 7, the board 6, and the cooling mechanism 23 in the second section 3Bb). This arrangement enables the air sucked from outside to hit the board 7 before reaching the position of the board 6. Therefore, as an example, the heat dissipating efficiency of the board 7 can be increased easily. Furthermore, among the components housed in the housing 3, the board 7 on which modules 8A and 8B are implemented and that is relatively heavy is located on the opposite side of the cooling mechanism 23 that is another heavy object with respect to the board 6 that is disposed at the center of the housing 3. Therefore, as an example, the weight balance of the television receiver 1 can be further improved. Therefore, as an example, when a user carries the television receiver 1, the user can handle more easily.

Furthermore, in the embodiment, as an example, the wall portion 3m of the housing 3 comprises an inlet 22a2 arranged near the fan 24, an inlet 22a3 arranged on the opposite side of the inlet 22a2 with respect to the board 6, and the inlet 22a1 arranged nearer to the electronic components 12, which is a heating element, than the inlets 22a2 and 22a3, as illustrated in FIGS. 3 and 10. By providing the inlet 22a2, the air flow is permitted to flow through the housing 3 more efficiently. Furthermore, an air flow S collected through the inlet 22a3 is divided into an air flow S2 flowing toward the fan 24 along a second surface 6b that is the rear surface of the board 6, and an air flow 51 flowing by passing through outside (flowing around, bypassing) an end 6c of the board 6 located opposite side of the fan 24 along a first surface 6a that is the front side of the board 6 toward the fan 24. Therefore, it is possible to cool the electronic components (heating elements) 12 implemented on both sides of the first surface 6a and the second surface 6b of the board 6.

Furthermore, in the embodiment, as an example, as illustrated in FIG. 10, the board 7 and the modules 8A and 8B are laid along the display device 4. Furthermore, the electronic components 12 are implemented on the board 25. A flexible cable 27 is also housed in the housing 3. The flexible cable 27 electrically connects the boards 6, 7, and 25, the display device 4, the connector 19, and the like. The flexible cable 27 is, for example, a flexible printed wiring board or a flat cable.

A plurality of antennas 26 is also housed in the housing 3, as illustrated in FIG. 9. In the embodiment, the antennas 26 connected to a communication module (for example, the module 8B) are provided in a manner separated from each other. In the embodiment, as an example, one of the antennas 26 is disposed near the end 3d and the end 3e (near the corner 3h) of the housing 3, and the other antenna 26 is disposed near the end 3e and the end 3f (near the corner 3i) of the housing 3. In this manner, as an example, the space diversity of the antennas 26 can be realized. The antennas 26 and the module 8B are electrically connected via a cable 28. Functions can be divided between the antennas 26 and 26, e.g., using one of the antennas 26 for transmissions and receptions, and using the other antenna 26 only for transmissions. Alternatively, one of the antennas 26 can be used as a backup of the other antenna 26.

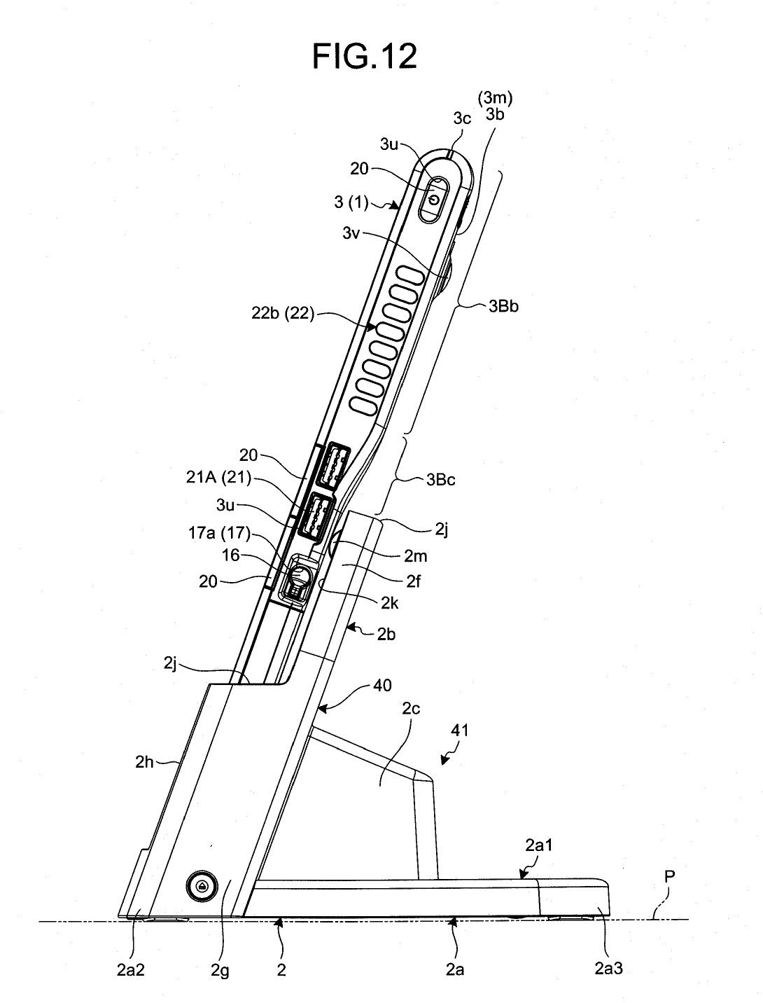

In the embodiment, as an example, the docking station 2 comprises a first support 2a and a second support 2b, as illustrated in FIGS. 11 and 12. The first support 2a is placed on the setting surface P (see FIG. 12), and functions as a platform (platform portion, bottom portion, lower portion, foundation portion, base, base portion, mounting portion, foot portion, foot, falling preventing portion, preventing portion). The second support 2b protrudes from (the bottom part of) the first support 2a upwardly of the setting surface P, and holds the housing 3 of the television receiver 1 at predetermined posture (position). In other words, the second support 2b functions as a holding portion (standing portion, vertical portion, upper portion, receive portion, maintaining portion, covering portion, abutting portion, contacting portion, guiding portion). The first support 2a and the second support 2b do not have to be clearly divided as separate components, and may be parts of a component. In the embodiment, as an example, the docking station 2 also comprises a protruding portion 2c that is arranged between the first support 2a and the second support 2b, and protrudes upwardly from the first support 2a and backwardly from the second support 2b. The protruding portion 2c has a function of a component housing 41 for housing components, as well as a support for supporting the second support 2b by being interposed between the first support 2a and the second support 2b. The docking station 2, the first support 2a, the second support 2b, and the protruding portion 2c are examples of a support that supports the television receiver (electronic device) 1. The first support 2a, the second support 2b, and the protruding portion 2c can be realized in various specifications (e.g., shapes, structures, and number). The docking station 2 is electrically and mechanically connected to the television receiver (electronic device) 1 positioned at a predetermined position (mounted position, holding position, placed position) of the docking station 2.

The docking station 2 can provide various functions related to the television receiver (electronic device) 1 mounted on the docking station 2. The docking station 2 can function as a stand for keeping the display screen 4a standing, for example. In such a case, the docking station 2 can have a function of setting the angle of the display screen 4a (the posture of the television receiver 1) variably. This will be described later. The docking station 2 can also function as a charger for the television receiver 1, for example. In such a case, the docking station 2 can function as a charger that is electrically connected to the television receiver 1 over a wire, or can function as a charger that performs non-contact charging (wireless charging). In such a case, a non-contact charging module is comprised in the second support 2b, as an example. The docking station 2 can also function as a connector (a hub for connectors, a device for relaying data, signals, and the like) that increases the number of connectors that are electrically connected the television receiver 1, for example. The docking station 2 can also function as a speaker of the television receiver 1, for example. The docking station 2 can also have, for example, a cooling function for the television receiver 1. In such a case, as an example, a ventilation channel, a fan, and the like are installed in a housing 40 of the docking station 2, and the docking station 2 can facilitate or promote cooling of the television receiver 1 by means of the air passing through the ventilation channel. The ventilation channel can have an opening facing the vent hole 22 on the television receiver 1. The docking station 2 also may have a cooling module facing the television receiver 1, as an example. The docking station 2 can also have a function of an alternating current (AC) adapter, for example.

Furthermore, in the embodiment, as an example, the docking station 2 has, at least partially, a hollow structure. The docking station 2 comprises the housing 40. At least a part of various components such as a board, a connector, an electronic component, and a harness (not illustrated) is housed in the housing 40. The housing 40 can be made of a synthetic resin material or a metallic material (a synthetic resin material in the embodiment, as an example). Furthermore, in the embodiment, as an example, a frame (frame member, backbone member, highly stiff member, stiff member, strong member; not illustrated) is disposed in the housing 40. The frame can be made of a metallic material or a synthetic resin material (in the embodiment, a metallic material, as an example). In the embodiment, as an example, a board, and connectors, electronic components, and the like implemented on the board are housed in a component housing 41 that is a part of the housing 40 and is structured as the protrusion 2c.

In the embodiment, as an example, the first support 2a is thin in a side view along the setting surface P (the line of sight illustrated in FIG. 12), and has an appearance of a rectangular shape (trapezoidal shape) in a plan view in perpendicular to the setting surface P, and has a flat shape (plate-like, wall-like) along the setting surface P, as illustrated in FIGS. 11 and 12. In the embodiment, as an example, the second support 2b protrudes in a direction slightly inclined backwardly from the vertical direction of an end 2a2 of the first support 2a (toward the rear side with the television receiver 1 mounted, the side nearer to an end 2a3 located on the opposite side of the end 2a2). The second support 2b keeps (supports, maintains, holds) a part of one end of the housing 3 of the television receiver (in the embodiment, the end 3e, as an example) from directions excluding the direction (in the embodiment, upward direction, as an example) in which the television receiver 1 is mounted on (inserted to) the predetermined position (holding position, held area), in other words, from the bottom, the backward, and the sideward directions (the left side and the right side), and in a manner surrounding (covering) the end of the housing 3 from the front side, as illustrated in FIGS. 11 and 12. The part along the end 3e (see FIGS. 1 to 3) can also be covered by the second support 2b. The second support 2b also functions as a guide for guiding the housing 3 of the television receiver 1 to a predetermined position when the television receiver 1 is moved (slid, displaced, inserted, mounted) to the predetermined position of the docking station 2. In other words, the second support 2b is an example of a guiding portion (guide portion, slide portion, sliding portion). In the embodiment, as an example, the second support 2b comprises wall portions 2e to 2h. The wall portion (first wall, first wall portion, bottom wall portion, lower wall portion) 2e is located under the housing 3 held at the predetermined position, and covers the housing 3 from the bottom. The wall portion (second wall, second wall portion, rear wall portion, back wall portion) 2f is located behind the housing 3, and covers the housing 3 from behind (rear side, rear surface side, back surface side, behind side). The wall portions (third wall, third wall portion, side wall portion) 2g are located on the side of the housing 3, and covers the housing 3 from the lateral directions. The wall portion (fourth wall, fourth wall portion, front wall portion) 2h is located in front of the housing 3, and covers the housing 3 from the front side. The wall portion 2e can be configured as a part of the first support 2a.

Furthermore, in the embodiment, as an example, the docking station 2 covers the television receiver 1 in a manner exposing the functioning parts of the television receiver (electronic device) 1, or in a manner communicating the functioning parts to the perimeter of the docking station 2. As an example, in the embodiment, the second support 2b comprises an opening 2i in a manner corresponding to the front side of the television receiver 1, as illustrated in FIG. 11. The opening 2i can be configured as a cutout portion or a through-hole, for example (in the embodiment, a cutout portion, as an example). In other words, in the embodiment, in a posture where the television receiver 1 is mounted on the docking station 2, the parts that are laid along the ends 3d and 3f, located on the right and the left sides of the front surface 3a of the housing 3, and that are not matched with the display screen 4a and the opening 3r are covered by (the wall portion 2h of) the second support 2b. Such an arrangement can better ensure the visibility of the display screen 4a, as an example. The end 3e, which is located at the bottom of the front surface 3a of the housing 3, may be covered by a covering member (for example, a part of the second support 2b, the first support 2a, or the housing 40, or a separate member that is not the housing 40).

In the embodiment, as an example, the docking station 2 holds the television receiver 1 in a state in which the vent holes 22 provided on the housing 3 of the television receiver 1 are exposed. As illustrated in FIGS. 3, 5, and 6, the vent holes 22 are provided on the second section 3Bb and the tilted section 3Bc of the housing 3, respectively. As it may be understood from FIGS. 3, 5, 7, and 11, each of the vent holes 22 is located at a position higher than an upper end (edge portion, side portion) 2j of each of the portions of the second support 2b, and is exposed without being covered by the docking station 2. Therefore, as an example, the air (air flow) flowing through the vent holes 22 is less interrupted by the docking station 2. The openings 3u of the connectors 21, the opening 17a of the component receptacle 17 for holding the component 16, the openings 3u of the operating modules 20 on the housing 3, and the like are also exposed. Therefore, in the embodiment, as an example, a component, a hand, a finger, and the like moving closer or making operations to the openings 3u and 17a is less interrupted by the docking station 2. Furthermore, such an arrangement enables the second section 3Bb of the housing 3 that is an example of an area for releasing a large amount of heat from the housing 3 to be exposed from the docking station 2. Therefore, as an example, compared with an arrangement in which the second section 3Bb is covered by the docking station 2, heat dissipation performance can be better increased. Furthermore, as an example, the cooling efficiency can be better increased.

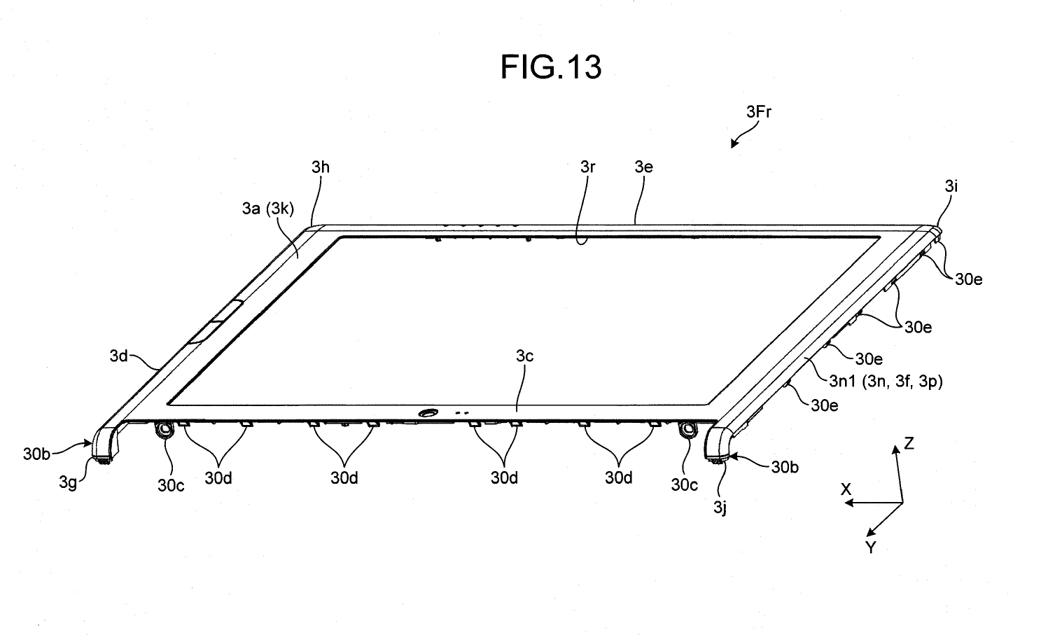

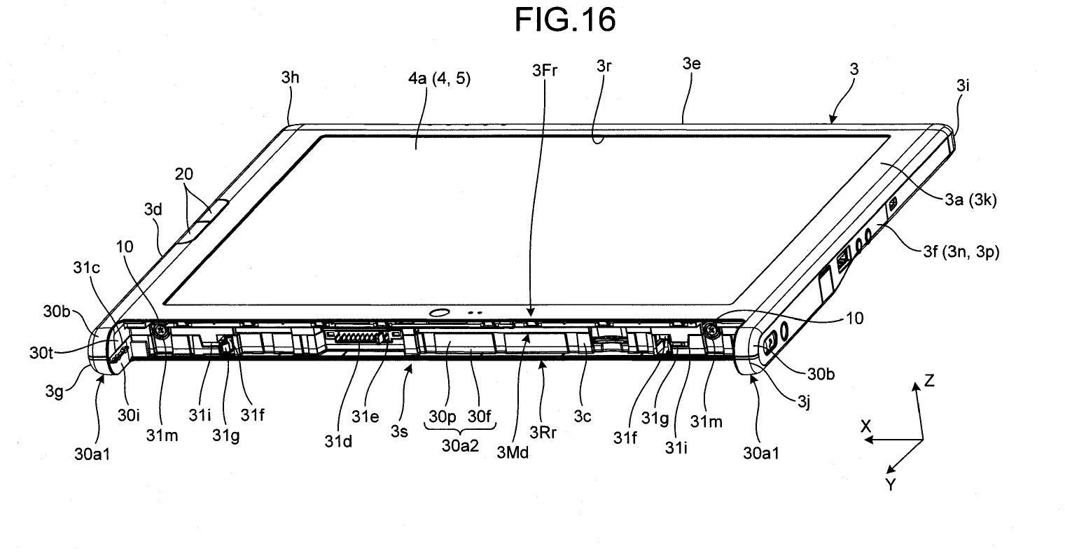

Furthermore, in the embodiment, as an example, as illustrated in FIG. 13, the first member (first housing member) 3Fr is formed in a rectangular (in the embodiment, an oblong shape, as an example) and frame-like shape viewed from the front and viewed from the rear. Specifically, the first member 3Fr comprises wall portions 3k and 3n1 (3n). The wall portions 3n1 (3n) are kept standing from the wall portion 3k on the perimeter of the wall portion 3k. The opening 3r is formed at the center of the first member 3Fr. The wall portion 3k that is a peripheral part of the opening 3r and the front surface 3a is structured in a band-like and plate-like shape. The first member 3Fr also comprises protrusions 30b. First supports 30a1 (see FIG. 16) located at the respective ends of the battery receptacle 3s in the longitudinal direction are respectively covered by the protrusions 30b from the front side. Each of the protrusions 30b is continuous from the wall portion 3k and the front surface 3a, and protrudes in the direction in which corresponding one of the end 3d and the end 3f extends. The tip side of each of the protrusions 30b is curved toward the wall portion 3m and the rear surface 3b (see FIGS. 5 and 7) to the outside of the housing 3 in a convexed arc-like shape, and is formed as a part of the end 3c and the side surface 3p. As illustrated in FIG. 8, the first member 3Fr covers the edges (peripheral parts) of the display device 4 and the input operation panel 5 from the front side. Therefore, the first member 3Fr is an example of a bezel (front bezel). Furthermore, the first member 3Fr is exposed except for a part facing the battery 18 (a part at (along) the end 3c). In other words, the first member 3Fr is an example of a shell.

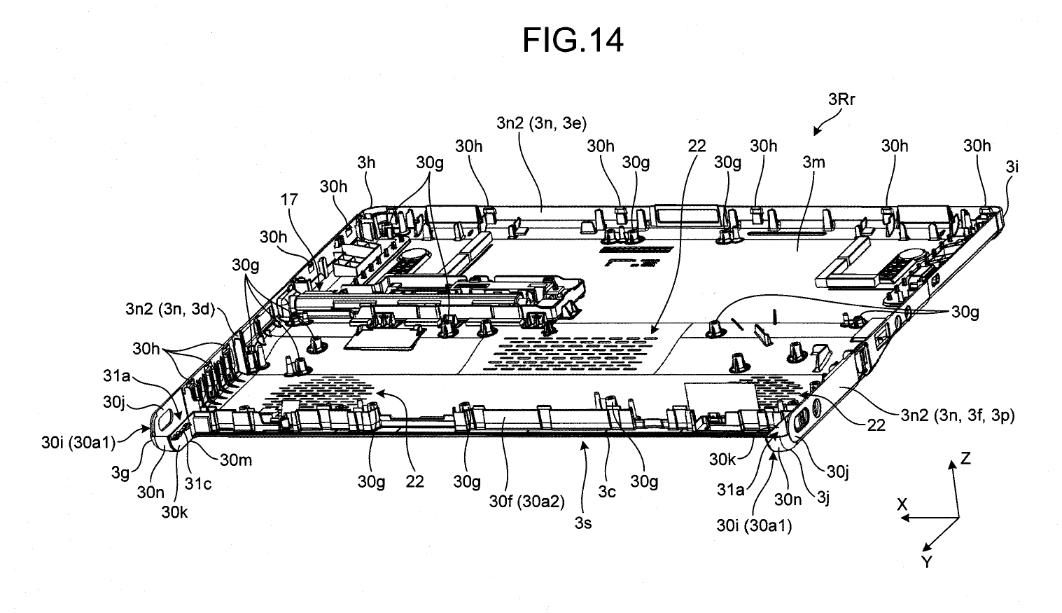

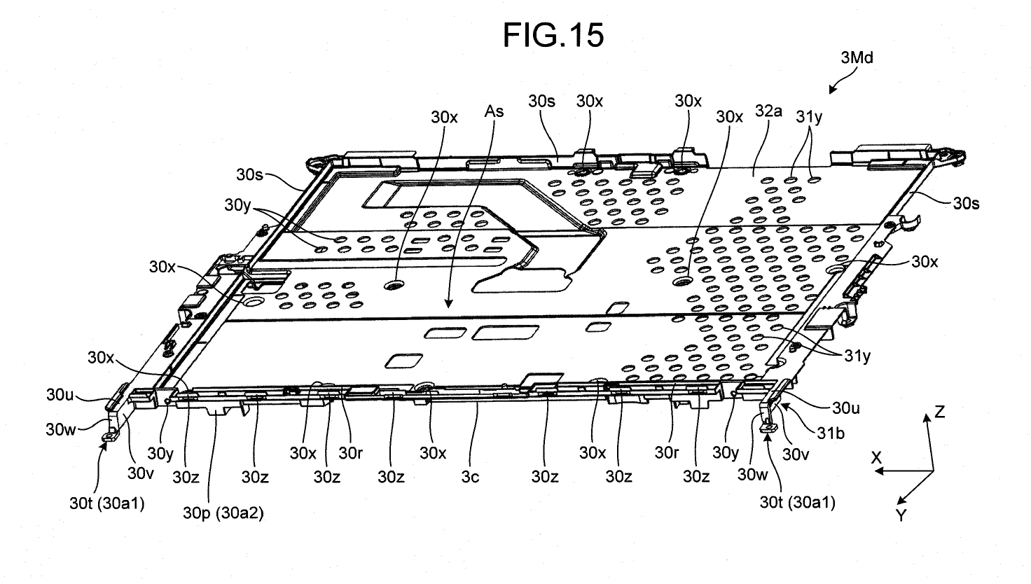

The first member 3Fr comprises coupled portions 30c, 30d, and 30e that are disposed along the outer perimeter of the first member 3Fr and are coupled to the other housing member (the second member 3Rr or the third member 3Md). The coupled portions 30c and the coupled portions 30d are disposed on a part of the first member 3Fr extending along the end 3c where the battery receptacle 3s is arranged. Each of the coupled portions 30c is formed as an opening (in the embodiment, a through-hole, as an example) through which a coupler, such as a screw 10, is inserted. The coupled portions 30c are respectively coupled to coupled portions 30y disposed on the other housing member (in the embodiment, the third member 3Md, as an example) via couplers such as the screws 10 (see FIG. 15). The coupled portions (engaged portions) 30d are respectively engaged with and coupled to coupled portions 30z (engaged portions, see FIG. 15) disposed on the other housing member (in the embodiment, the third member 3Md, as an example). The coupled portions 30e are disposed on each of the ends 3d, 3e, and 3f, but not on the end 3c of the first member 3Fr. The coupled portions (engaged portions) 30e are engaged with and coupled to coupled portions 30h (engaged portions, see FIG. 14) disposed on the other housing member (in the embodiment, the second member 3Rr, as an example). The coupled portions 30e are examples of a first engaged portion. The coupled portions 30h are examples of a second engaged portion.

Furthermore, in the embodiment, as an example, as illustrated in FIG. 14, the second member (second housing member) 3Rr is formed in a rectangular shape (in the embodiment, an oblong shape, as an example) viewed from in the front and viewed from the rear. The second member 3Rr as a whole is configured in a plate-like form. Specifically, the second member 3Rr comprises the wall portion 3m, wall portions 3n2 (3n), and a wall portion 30f. The wall portions 3n2 (3n) and 30f are kept standing from the wall portion 3m on the perimeter of the wall portion 3m. The wall portion 30f is structured as a part of the battery receptacle 3s and a part of a battery support (second support 30a2), and faces the battery 18. The second member 3Rr is exposed except for a part facing the battery 18 (a part at (along) the end 3c). In other words, the second member 3Rr is an example of the shell.

Coupled portions 30g that are coupled to the other housing member (the first member 3Fr or the third member 3Md) are disposed on the inner surface of the wall portion 3m in the housing 3. The coupled portions 30g are coupled to respective coupled portions 30x (see FIG. 15) disposed on the other housing member (in the embodiment, as an example the third member 3Md, as an example) via couplers such as the screws 10. Each of the coupled portions 30g is formed as a protrusion protruding from the wall portion 3m toward inside of the housing 3, and has a fixed portion to which the coupler is fixed (e.g., a hole with an internal screw). The wall portion 3m also comprises the component receptacle 17 in which the component 16 is received. The coupled portions 30h are disposed on the wall portions 3n, but not on the wall portion 30f. The coupled portions (engaged portions) 30h are engaged with and coupled to the respective coupled portions 30e (engaged portions, see FIG. 13) disposed on the other housing member (in the embodiment, the first member 3Fr, as an example).

The second member 3Rr comprises protrusions 30i each of which is a part of the corresponding first support 30a1 and is disposed at each end of the battery receptacle 3s in the longitudinal direction. Each of the protrusions 30i comprises wall portions 30j, 30k, 30m, and 30n. The wall portion 30j is continuous to the wall portions 3n2 (3n). The wall portion 30k is interspaced with the wall portion 30j and is laid along the wall portion 30j. The wall portion 30m extends between the wall portion 30j and the wall portion 30k, and is continuous to the wall portion 3m. The wall portion 30n extends between the wall portion 30j and the wall portion 30k at the tip of the wall portion 30m. In a space surrounded by the wall portions 30j, 30k, 30m, and 30n of the protrusion 30i, a recessed portion (space, component housing, housing) 31a that opens to the inside of the housing 3 (on the side of the end 3e and the wall portion 3k) is formed by the wall portions 30j, 30k, 30m, and 30n. Each of the wall portions 30n is continuous to the corresponding wall portion 30m, is curved in an arc-like shape to the outside of the housing 3 in a manner convexed toward the side of the wall portion 3k and the front surface 3a (see FIGS. 5 and 7), and is formed as a part of the end 3c and the side surface 3p.

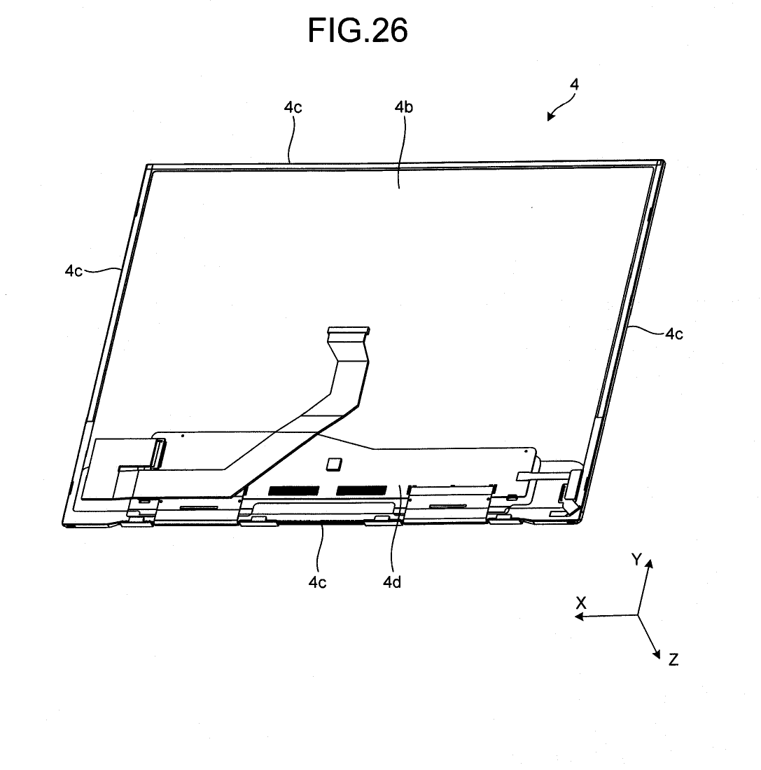

Furthermore, in the embodiment, as an example, as illustrated in FIG. 15, the third member (the third housing member) 3Md is formed in a rectangular shape (in the embodiment, an oblong shape, as an example) viewed from the front and viewed from the rear. Furthermore, the third member 3Md as a whole is formed in a plate-like form. Specifically, the third member 3Md comprises wall portions 32a, 30p, 30r, and 30s. The wall portion 32a is formed in a rectangular and plate-like shape, and supports a rear surface 4b of the display device 4 (see FIG. 26). The wall portion 32a is an example of a first wall portion. The wall portions 30p, 30r, and 30s are kept standing from the wall portion 32a on the perimeter of the wall portion 32a. The wall portion 30p is located at (laid along) the end 3c, and is structured as a part of the battery receptacle 3s and the battery support (second support 30a2), and faces the battery 18. The wall portion 30p is an example of a side wall. The wall portion 30r is located at (laid along) the end 3c and located on the side closer to the inside of the housing 3 than the wall portion 30p, faces a side surface 4c (covers the side surface 4c), and supports the side surface 4c of the display device 4 (see FIG. 26). The wall portions 30s are located at (laid along) the end 3d, 3e, and 3f, respectively, and are arranged on the side closer to the inside of the housing 3 than the wall portions 3n of the first member 3Fr or of the second member 3Rr, faces the side surface 4c (covers the side surface 4c), and supports the side surface 4c of the display device 4. Between the respective wall portions 3n and wall portions 30s, a recessed portion (space, component housing, housing) housing therein components such as a harness, a board, a connector, and the like is formed. The wall portions 30s are examples of an end. Furthermore, the wall portions 30r and 30s are examples of a second wall portion. The wall portion 30p is an example of a first end, and the wall portions 30s are examples of a second end.

The third member 3Md also comprises protrusions 30t each of which forms a part of the first support 30a1 located at each end of the battery receptacle 3s in the longitudinal direction. Each of the protrusions 30t comprises wall portions 30u, 30v, and 30w. The wall portion 30u is paralleled with (in parallel with) the wall portion 32a. The wall portion 30v extends from the wall portion 30p in a direction crossing (in the embodiment, a direction in perpendicular to, as an example) the wall portion 30p. The wall portion 30v also extends in a direction crossing (in the embodiment, a direction in perpendicular to, as an example) the wall portion 32a. The wall portion 30w extends between the tip of the wall portion 30u and the tip of the wall portion 30v. A recessed portion (space, component housing, housing) 31b opening to the inside of the housing 3 (on the side of the end 3e and on the side of the wall portion 3m) is formed by the wall portions 30u, 30v, and 30w. The recessed portions 31a formed in the second member 3Rr and the recessed portions 31b formed in the third member 3Md are laid on top of each other along the thickness direction of the housing 3, to form component housings that are disposed at respective ends of the battery 18 in the longitudinal direction, and that open to the side of the end 3e of the housing 3.

The third member 3Md also comprises the coupled portions 30x, 30y, and 30z that are coupled to the other housing member (the first member 3Fr or the second member 3Rr). The coupled portions 30x are disposed on the wall portion 32a, and are coupled to the other housing member (in the embodiment, the second member 3Rr, as an example) using couplers such as the screws 10. Each of the coupled portions 30x corresponds to each of the coupled portions 30g (see FIG. 14), and is formed as an opening (in the embodiment, a through-hole, as an example) through which a coupler such as the screw 10 is inserted. The coupled portions 30y are disposed on the wall portion 30p, and are coupled with the other housing member (in the embodiment, the first member 3Fr, as an example) via couplers such as the screws 10. Each of the coupled portions 30y corresponds to each of the coupled portions 30c, and comprises a coupled portion (in the embodiment, a hole with an internal screw) to which a coupler such as the screw 10 is coupled. The coupled portions 30z are disposed on the wall portion 30p, and are respectively engaged with and coupled to the coupled portions 30d (engaged portions, see FIG. 13) disposed on the other housing member (in the embodiment, the first member 3Fr, as an example).

In the embodiment, in the arrangement in which the battery 18 is received in (mounted on) the battery receptacle 3s, the third member 3Md is not exposed from the housing 3. Therefore, in the embodiment, as an example, a process for improving the appearance, such as painting, does not have to be applied to the third member 3Md. In the embodiment, as an example, the second member 3Rr and the third member 3Md are made of metallic materials, and the first member 3Fr is made of a synthetic resin material. In other words, in the embodiment, as an example, the stiffness of the housing 3 is provided mainly by the second member 3Rr and the third member 3Md. Therefore, the stiffness of the first member 3Fr can be reduced compared with an arrangement not having the third member 3Md. In this manner, by distributing functions among a plurality of members, advantageous effects, such as a reduction in labors required in the production, may be achieved.

Furthermore, in the embodiment, as an example, as illustrated in FIG. 15, the wall portion 32a of the third member 3Md comprises a plurality of openings 31y (through-holes, as an example). The openings 31y allow, as an example, the third member 3Md, and the television receiver 1 in turn, to be more light-weighted. Furthermore, as an example, the openings 31y can improve ventilation in the housing 3. Furthermore, as illustrated in FIG. 8 as well, in the embodiment, as an example, the openings 31y are not arranged in a section As facing (coming in face with) the board 6 and the fan 24, but the openings 31y are arranged in a section Ao facing (coming in face with) a section between the second member 3Rr and the third member 3Md on the opposite side of the fan 24 with respect to the board 6. In this manner, according to the embodiment, as an example, the air passing through the openings 31y formed on the wall portion 32a can better flow from a section on the opposite side of the fan 24 with respect to the board 6, pass outside of (flow around, bypass) the end 6c (edge, see FIG. 10) of the board 6 which is on the opposite side of the fan 24, and flow into the opposite side (the second surface 6b) of the board 6 with respect to the third member 3Md.

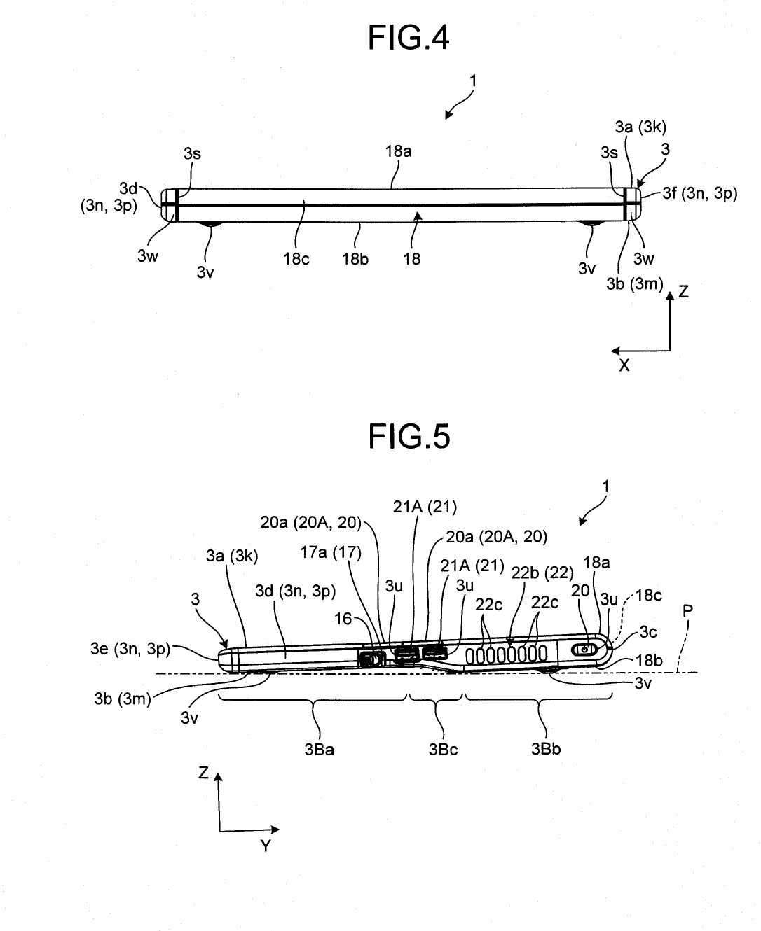

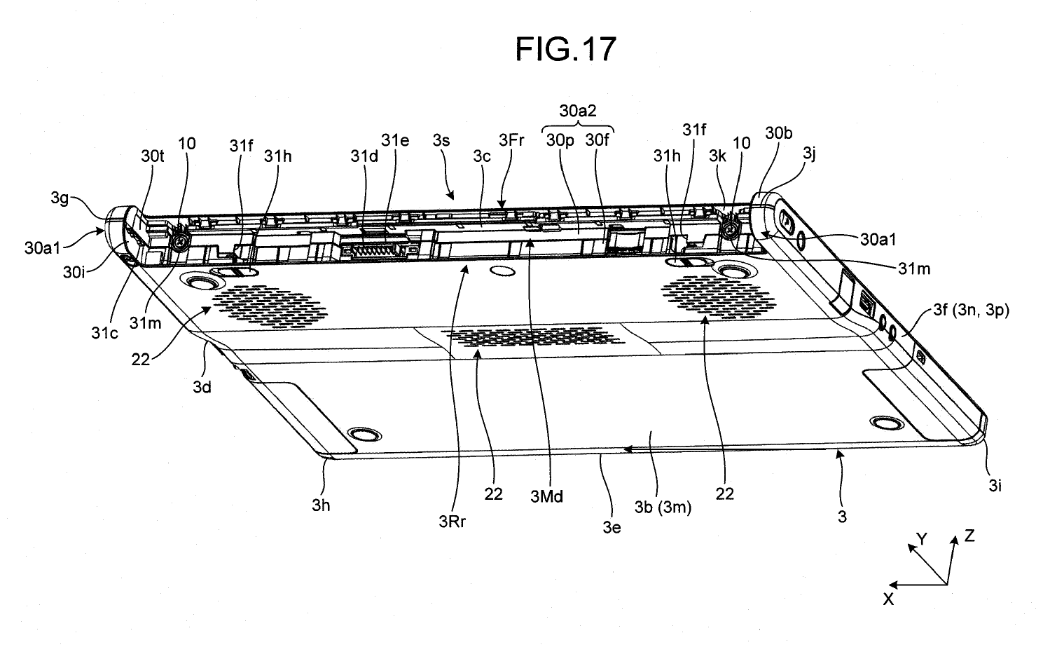

In the embodiment, as an example, as illustrated in FIGS. 16 and 17, the battery receptacle 3s is formed as a cutout portion (recessed portion, opening) formed on the end 3c of the housing 3. When the battery 18 is received by (mounted on) the battery receptacle 3s, as illustrated in FIGS. 4, 5, and 7, for example, a surface 18a of the battery 18 and the front surface 3a of the housing 3 become continuous, a surface 18b on the opposite side of the surface 18a of the battery 18 and the rear surface 3b of the housing 3 become continuous. The surface 18a and the surface 18b are connected via a surface (curved surface) 18c curving in an arc-like form protruding outwardly.

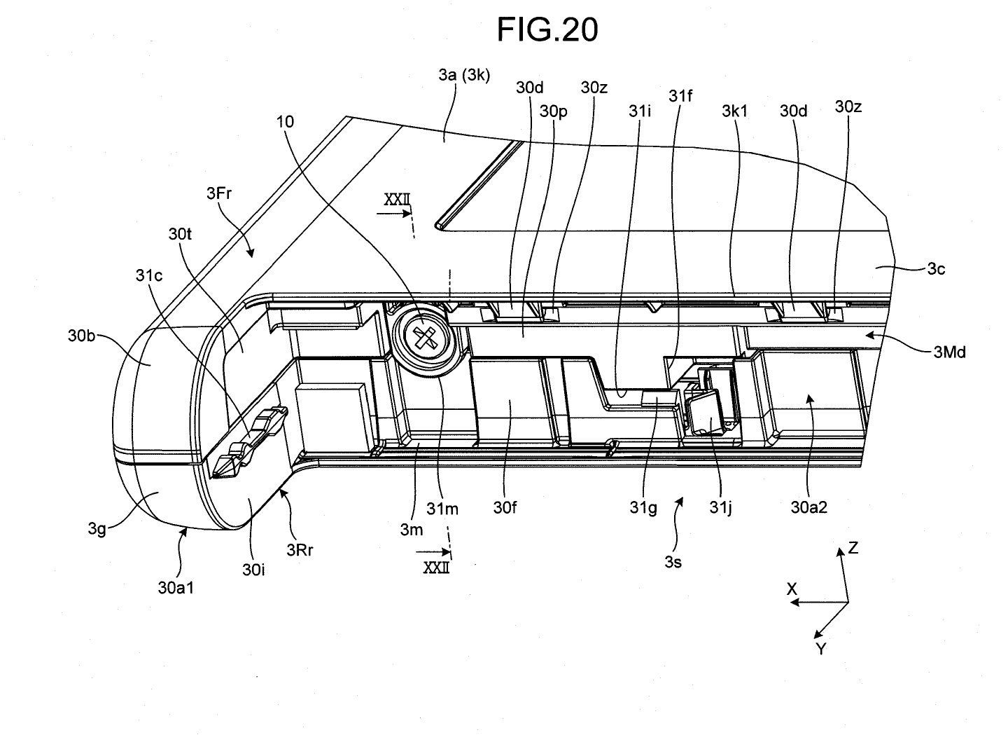

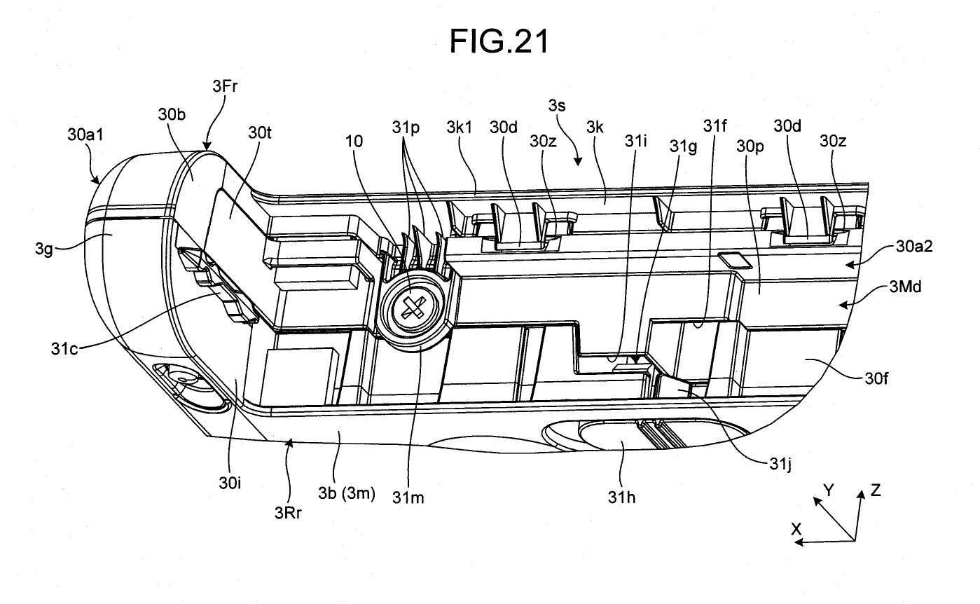

In the embodiment, as an example, the battery receptacle is formed by a combination of the three housing members (the first member 3Fr, the second member 3Rr, and the third member 3Md). The battery 18 is mainly supported by the second member 3Rr and the third member 3Md. A part of the battery 18 (in the embodiment, a part closer to the housing 3, a part along the end 3c of the housing 3, as an example) is covered by the first member 3Fr, the second member 3Rr, and the third member 3Md. In the embodiment, as an example, both ends 18d of the battery 18 in the longitudinal direction are supported by the respective first supports 30a1. One end of the battery 18 along the short side direction (an end laid along the end 3c of the housing 3) 18e is supported by the second support 30a2. Each of the first supports 30a1 comprises the protrusion 30i disposed on the second member 3Rr and the protrusion 30t disposed on the third member 3Md. The second support 30a2 comprises the wall portion 30f of the second member 3Rr and the wall portion 30p of the third member 3Md. The first support 30a1 and the second support 30a2 are examples of the battery support. In the embodiment, as an example, as illustrated in FIGS. 20 and 21, a part of the wall portion 30f of the second member 3Rr and a part the wall portion 30p of the third member 3Md both of which face the battery receptacle 3s are arranged side by side along the thickness direction of the housing 3.

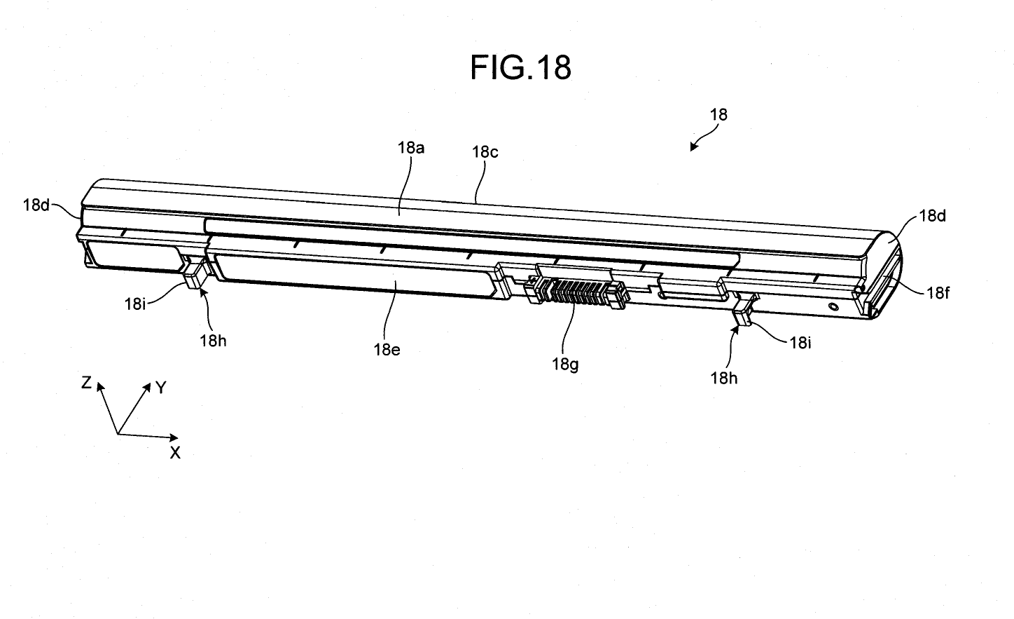

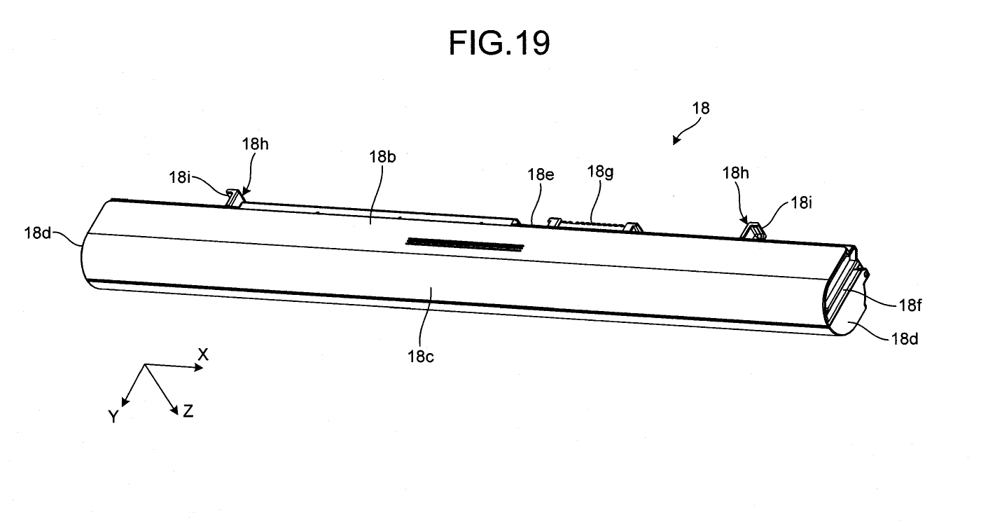

In the embodiment, as an example, as illustrated in FIGS. 18 and 19, each of the ends 18d of the battery 18 in the longitudinal direction comprises an engaged portion 18f that is engaged with the first support 30a1. Each of the engaged portions 18f is formed as a groove (recessed portion, opening) formed along an in-and-out direction of the battery 18 (mounting direction, attaching and removing direction, in the embodiment, as an example, the direction along the front surface 3a and the ends 3d and 3f, the Y direction), as an example. Correspondingly, each of the first supports 30a1 comprises an engaged portion 31c that is engaged with the corresponding engaged portion 18f, as illustrated in FIGS. 16 and 17. Each of the engaged portions 31c is formed as a protrusion (projection, wall) that is disposed on at least one of the second member 3Rr and the third member 3Md (in the embodiment, the second member 3Rr, as an example) and is inserted into the engaged portion 18f that is a groove. When a user and the like holding the battery 18 moves the battery 18 closer to the battery receptacle 3s and inserts the battery 18 into the battery receptacle 3s, the battery 18 is moved to a predetermined position (mounted position, coupled position) as the engaged portions 18f are guided by the respective engaged portions 31c. In other words, the engaged portions 31c and the engaged portions 18f are examples of a support and a guide portion (guiding portion).

On the end 18e of the battery 18 in the short side direction, a connector 18g and engaged portions 18h that are to be engaged with the second support 30a2 are disposed. The connector 18g protrudes from the end 18e of the battery 18. Correspondingly, a connector 31d that is mechanically and electrically connected to the connector 18g is disposed on the second support 30a2, as illustrated in FIGS. 16 and 17. The connector 31d is electrically connected to the board 6, and is exposed through an opening 31e disposed on the second support 30a2. The engaged portions 18h are structured as protrusions disposed at a plurality of points (in the embodiment, two, as an example) that are separated from each other along the longitudinal direction of the battery 18. A claw portion (engaged portion, hook portion, hook) 18i is formed on the tip of each of the engaged portions 18h. Correspondingly, openings (recessed portions) 31f into which the respective engaged portions 18h are inserted are disposed on the second support 30a2. Each of the opening 31f is formed as a gap (cutout) formed between the wall portion 30f of the second member 3Rr and the wall portion 30p of the third member 3Md in a boundary area between the wall portion 30f of the second member 3Rr and the wall portion 30p of the third member 3Md, as illustrated in FIGS. 20 and 21. A gap can be manufactured more easily compared with a through-hole. Therefore, according to the embodiment, as an example, a labor for manufacturing the openings 31f can be reduced easily. Furthermore, in the embodiment, as an example, an engaged portion (movable portion) 31g supported on the housing 3 (at least one of the second member 3Rr and the third member 3Md; in the embodiment, both, as an example) in a slidable (movable, displaceable) manner is disposed in the opening 31f. A claw portion (engaged portions, hook portion, hook) 31j that is engaged with the corresponding claw portion 18i is disposed on the tip of each of the engaged portions 31g. The engaged portions 31g are connected to a manipulator (component, slider) 31h disposed in a manner exposed from the housing 3, and operate (interoperate) with the manipulator 31h. The engaged portions 31g are moved in a manner guided by respective guide portions 31i of the housing 3. In the embodiment, as an example, each of the guide portions 31i is formed as a gap (cutout, silt) formed between the ends (end edges, edges, sides) of the wall portion 30f of the second member 3Rr and the wall portion 30p of the third member 3Md in the boundary area of the wall portion 30f of the second member 3Rr and the wall portion 30p of the third member 3Md. A gap can be manufactured more easily compared with a through-hole. Therefore, according to the embodiment, as an example, a labor for manufacturing the engaged portions 31g can be reduced easily. In such a structure, as the battery 18 is guided into the battery receptacle 3s, the engaged portions 18h are inserted into the respective openings 31f. When a user moves the manipulator 31h from a free side (releasing side) to a locking side (fixing side) using a finger or a hand while the battery 18 is positioned at a predetermined position (mounted position, coupled position) with respect to the housing 3, the claw portion 31j of each of the engaged portions 31g is engaged with the claw portion 18i disposed on each of the engaged portions 18h, and the battery 18 is locked (fixed) at a predetermined position (mounted position, incoming position).

Furthermore, in the embodiment, as an example, as illustrated in FIGS. 20 and 21, the wall portion 30f of the second member 3Rr and the wall portion 30p of the third member 3Md covered by the battery 18 have a recessed form or projected form (recessed portion and projected portion) recessed or projected in the normal direction (Y direction) of the wall portion 30f and the wall portion 30p. In this manner, the stiffness of the end 3c of the housing 3 covered by the battery 18 can be improved easily.

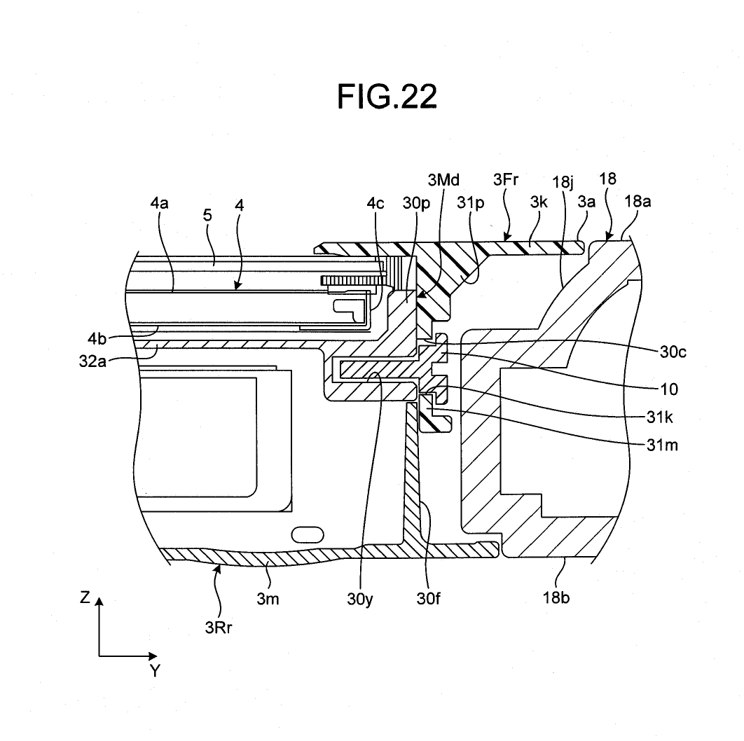

Furthermore, in the embodiment, as an example, as illustrated in FIGS. 21 and 22, the coupled portions 30c and 30d disposed on the first member 3Fr are coupled to at least one of the second member 3Rr and the third member 3Md (in the embodiment, the third member 3Md, as an example) from the outside of the housing 3. Specifically, each of the coupled portions 30c comprises a protrusion 31m having an opening 31k through which a coupler such as the screw 10 is passed, as illustrated in FIG. 22. The protrusion 31m protrudes from the wall portion 3k toward the wall portion 3m in the thickness direction of the housing 3. The protrusion 31m extends along the surface (external surface) of the wall portion 30p of the third member 3Md and of the wall portion 30f of the second member 3Rr. In other words, the protrusions 31m cover the wall portions 30p and 30f from the outside of the housing 3. Each of the coupled portions (engaged portions) 30d is engaged with the corresponding coupled portion (engaged portion) 30z disposed on an end of the wall portion 30p of the third member 3Md on the side closer to the wall portion 3k from the outside of the housing 3, as illustrated in FIG. 21. In an arrangement in which the coupled portions 30c and 30d of the first member 3Fr cover at least one of the second member 3Rr and the third member 3Md from the outside of the housing 3 when the battery 18 is removed, as an example, the coupling achieved by the coupled portions 30c and 30d can be released easily.

Furthermore, in the embodiment, as an example, as illustrated in FIG. 22, the screw 10 coupled to the coupled portion 30c disposed on the first member 3Fr and to the coupled portion 30y disposed on at least one of the second member 3Rr and the third member 3Md (in the embodiment, as an example the third member 3Md) is positioned on the opposite side of the display screen 4a with respect to the display device 4. Therefore, as an example, compared with an arrangement in which the screw 10 and the display device 4 come on top of each other in a direction along the display screen 4a (an arrangement in which the screw 10 is positioned along the normal direction of the side surface 4c with respect to the display device 4), the length by which the housing 3 extends out of the side surface (edge) 4c of the display screen 4a viewed from the front can be reduced further. Therefore, as an example, the size of the housing 3 with respect to the size of the display device 4 can be further reduced easily.

Furthermore, in the arrangement according to the embodiment, each of the protrusions 31m extends in a direction moving away from the wall portion 3k, and the point (tip, end) of each of the protrusions 31m and each of the coupled portions 30d are separated from each other. Therefore, as an example, when an operator, after releasing the coupling of the coupled portions 30c and the coupled portion 30y, applies a force to (the tip of) the protrusion 31m in direction which the protrusion 31m is removed from the wall portions 30p and 30f (the direction toward the right, the direction toward the upper right in FIG. 22) with a hand, a finger, or a tool (e.g., a slotted screwdriver), the moment arm to the coupled portion 30d is further extended. Therefore, the engagement between the coupled portion 30d and the coupled portion 30z can be released easily.

Furthermore, by disposing the screw 10 behind the display device 4, the moment arm can be further better extended. Protrusions (wall portions, ribs) 31p extending in a direction crossing both of the protrusion 31m and the wall portion 3k are formed at the root (base end) of the protrusion 31m. Therefore, according to the embodiment, when the protrusion 31m is bent, the root can be better prevented from being deformed.

Furthermore, in the embodiment, as an example, as illustrated in FIGS. 21 and 22, the wall portion 3k extends (protrudes) out from the wall portion 30p in a direction moving away from the center of the housing 3. Therefore, as an example, when an operator, after releasing the engagement between the coupled portions 30c and the coupled portion 30y, applies a force to an end (end portions, side portion) 3k1 of the wall portion 3k in a direction moving away from the wall portion 3m (the direction toward the top, the direction toward the upper left in FIG. 22) with a hand, a finger, or a tool, the moment arm to the coupled portion 30d is further extended. Therefore, the engagement between the coupled portion 30d and the coupled portion 30z can be released easily. Furthermore, correspondingly to the extended portion of the wall portion 3k, a recessed portion 18j is formed on the battery 18. Therefore, the housing 3 is better prevented from being thick.

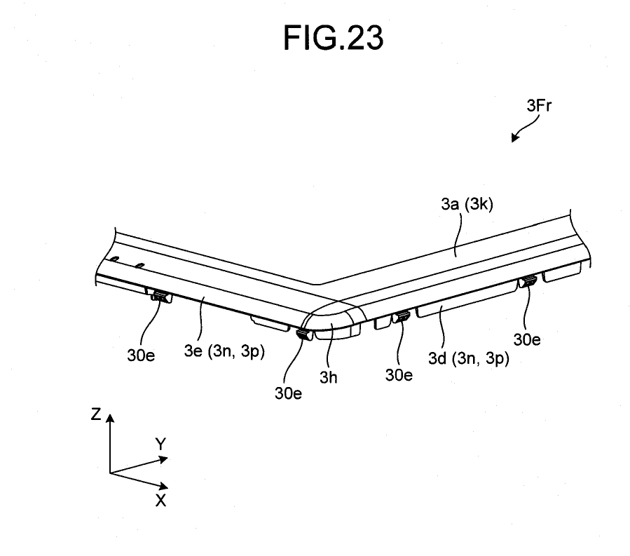

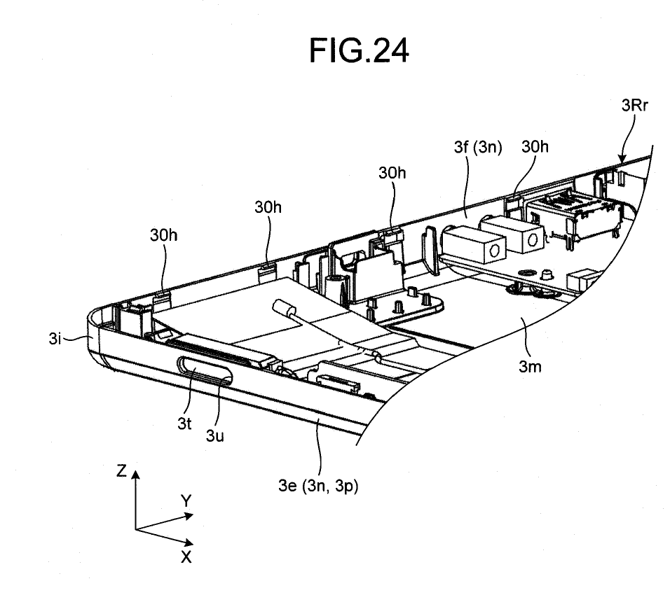

Furthermore, in the embodiment, as an example, as illustrated in FIGS. 23 and 24, the coupled portions 30e arranged on the first member 3Fr and the coupled portions 30h arranged on at least one of the second member 3Rr and the third member 3Md (in the embodiment, the second member 3Rr, as an example) are disposed nearer to the inside of the housing 3 than the wall portions 3n of the housing 3 on the ends 3d, 3e, and 3f, but not on the end 3c along the side of the battery receptacle 3s. In other words, the coupled portions 30e and 30h are covered by at least one of the first member 3Fr and the third member 3Md. Therefore, according to the embodiment, as an example, the coupled portions 30e and 30h can be prevented from being exposed. Therefore, for example, inconvenience caused by the coupled portions 30e and 30h being exposed from the housing 3, such as the coupling is more easily released or disfigurement is caused, can be prevented.

Furthermore, in the embodiment, as an example, coupling between the first member 3Fr and at least one of the second member 3Rr and the third member 3Md is based on an engagement (hooking) between the coupled portions, except that the coupling between the coupled portions 30c and the coupled portion 30y, which are covered by the battery 18, is via couplers such as the screws 10. Therefore, according to the embodiment, as an example, by providing a coupled portion that is more securely coupled via couplers to at least to the end 3c, the first member 3Fr and at least one of the second member 3Rr and the third member 3Md can be coupled more securely. At the same time, inconvenience caused by an increased number of locations coupled via couplers, such as the size or a weight increase, can be prevented.

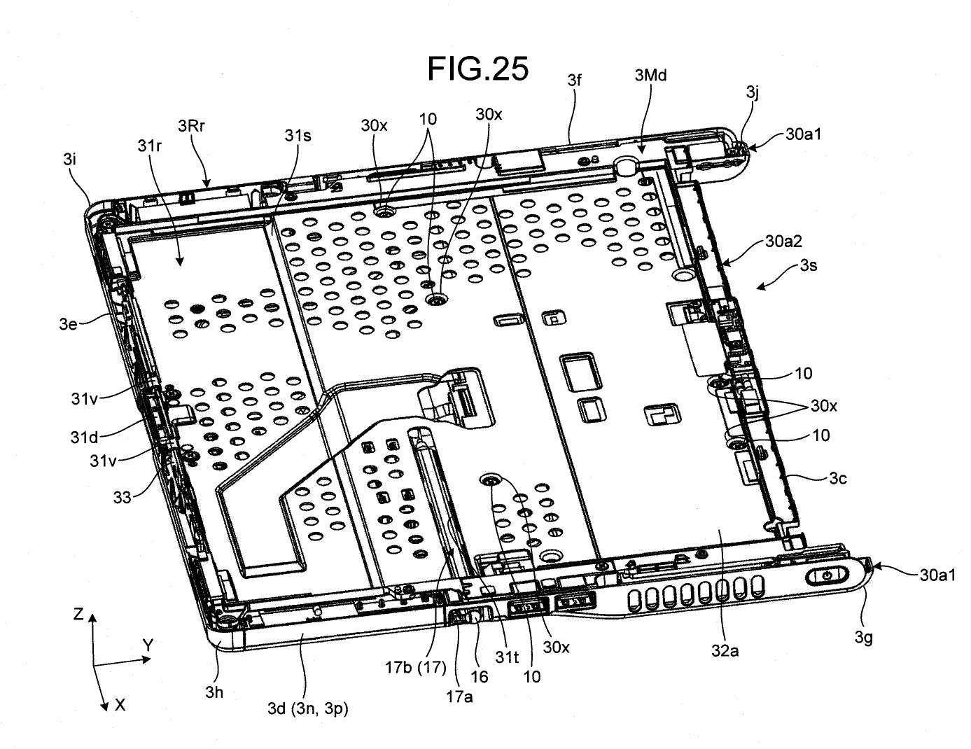

Furthermore, in the embodiment, as an example, as illustrated in FIG. 25, the second member 3Rr and the third member 3Md are coupled via couplers such as the screws 10, and the coupled portions 30x and 30g coupled with the couplers are covered by the display device 4 or the first member 3Fr. Therefore, according to the embodiment, as an example, the coupled portions 30x and 30g coupling the second member 3Rr and the third member 3Md that are the two housing members mainly for maintaining the stiffness and the strength can be prevented from being exposed from the housing 3. Therefore, for example, inconvenience caused by the coupled portions 30x and 30g being exposed, such as the coupling is more easily released or disfigurement is caused, can be prevented.

Furthermore, in the embodiment, as an example, the wall portion 32a of the third member 3Md comprises a recessed portion (opening) 31r recessing toward the second member 3Rr. Specifically, the recessed portion 31r is disposed side by side (in parallel) with the ends 3c and 3e and extends between the ends 3d and 3f facing each other. A wall portion 31s is disposed in a step-like form (in a shape of an inclined surface) in the boundary area of the recessed portion 31r. A board (circuit board) 4d disposed along the rear surface 4b of the display device 4 illustrated in FIG. 26 is housed in the recessed portion 31r. The wall portion 31s can improve the stiffness of the third member 3Md easily. Therefore, according to the embodiment, as an example, the recessed portion 31r can improve stiffness of the third member 3Md, while ensuring the space (area) for housing the board 4d of the display device 4.

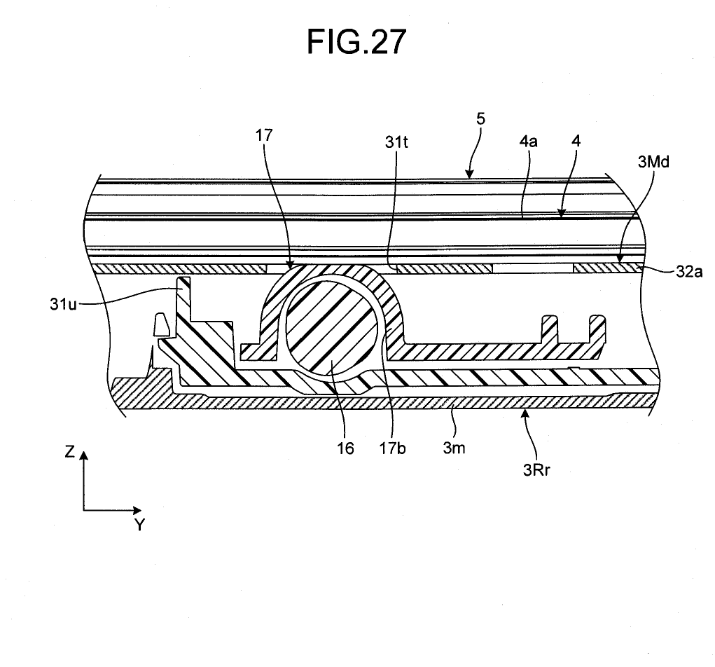

Furthermore, in the embodiment, as an example, as illustrated in FIGS. 25 and 27, the component receptacle 17 holding the component 16 is disposed between the second member 3Rr and the third member 3Md. In the embodiment, as an example, an opening 31t is arranged on the wall portion 32a of the third member 3Md in a manner corresponding to the component receptacle 17. The opening 31t is an example of a so-called clearance hole for preventing a wall portion (housing, tube, holding portion, peripheral wall portion) 17b of the component receptacle 17 from abutting against the wall portion 32a. Therefore, according to the embodiment, as an example, the wall portion 17b of the component receptacle 17 can be better prevented from being deformed by a force applied to the housing 3 or the display device 4 being communicated to the component receptacle 17 via the wall portion 32a, and the component 16 from being difficult to be taken in and out of the component receptacle 17. Furthermore, in the embodiment, as an example, as illustrated in FIG. 27, the wall portion 17b of the component receptacle 17 is fitted into the opening 31t. Therefore, the housing 3 can be better prevented from being thick on the component receptacle 17 and partly on the third member 3Md, compared with an arrangement in which the wall portion 17b is not fitted in the opening 31t. Furthermore, in the embodiment, as an example, a wall portion (protrusion, support) 31u extending between the wall portion 32a of the third member 3Md and the wall portion 3m of the second member 3Rr is disposed on a part neighboring to (near) the opening 31t. The wall portion 31u extends in a direction crossing (in the embodiment, direction in perpendicular to, as an example) the wall portion 32a and the wall portion 3m, and is interposed between the wall portion 32a and the wall portion 3m. When a force is applied to one of the wall portion 32a and the wall portion 3m in a direction moving one closer to the other, the wall portion 31u withholds of the force (functions as a support), and prevents the one from moving closer to the other. The stiffness and the strength tend to be lower at a part where the opening 31t is formed, compared with a part where the opening 31t is not formed. Therefore, in the embodiment, as an example, the wall portion 31u is provided so that the advantage achieved by the opening 31t can be achieved while better suppressing the disadvantage of the opening 31t.

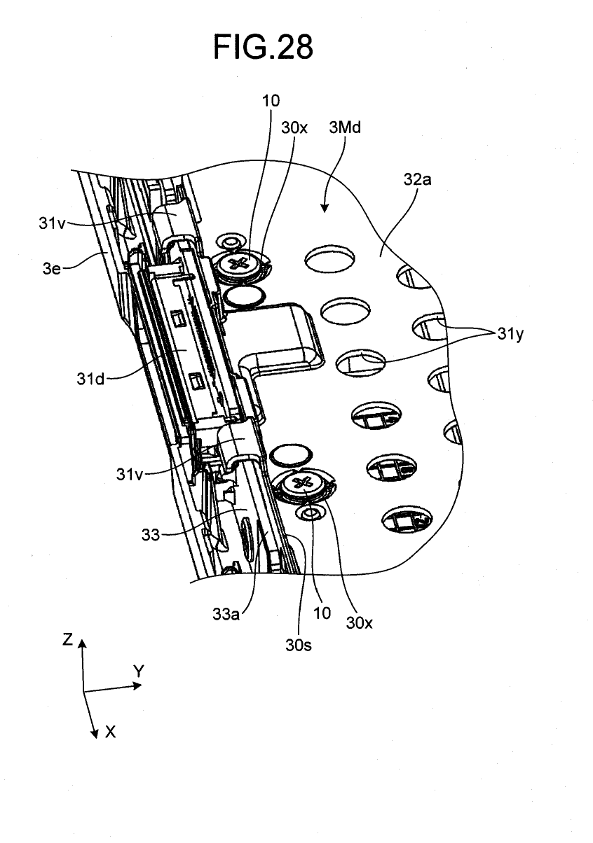

Furthermore, in the embodiment, as an example, the third member 3Md has a function of supporting various components. As illustrated in FIG. 28, the third member 3Md comprises engaged portions 31v for supporting a board (circuit board) 33 on which the connector (electronic component, component) 31d is disposed. The board 33 is disposed in an orientation along the end 3e of the housing 3, facing the wall portions 3n of the housing 3, and crossing (in the embodiment, in perpendicular to, as an example) the wall portion 32a of the third member 3Md. Each of the engaged portions 31v is configured to protrude from the end of the wall portion 32a in a hook-like shape. Each of the engaged portions 31v extends across one side of the board 33 and the other side, and is hooked onto an edge 33a of the board 33. Therefore, according to the embodiment, as an example, the board 33 can be hooked onto the third member 3Md using the third member 3Md. Therefore, according to the embodiment, as an example, the board 33 can be supported in a relatively simple manner while components are being assembled on the board 33 or after the components are assembled on the board 33.

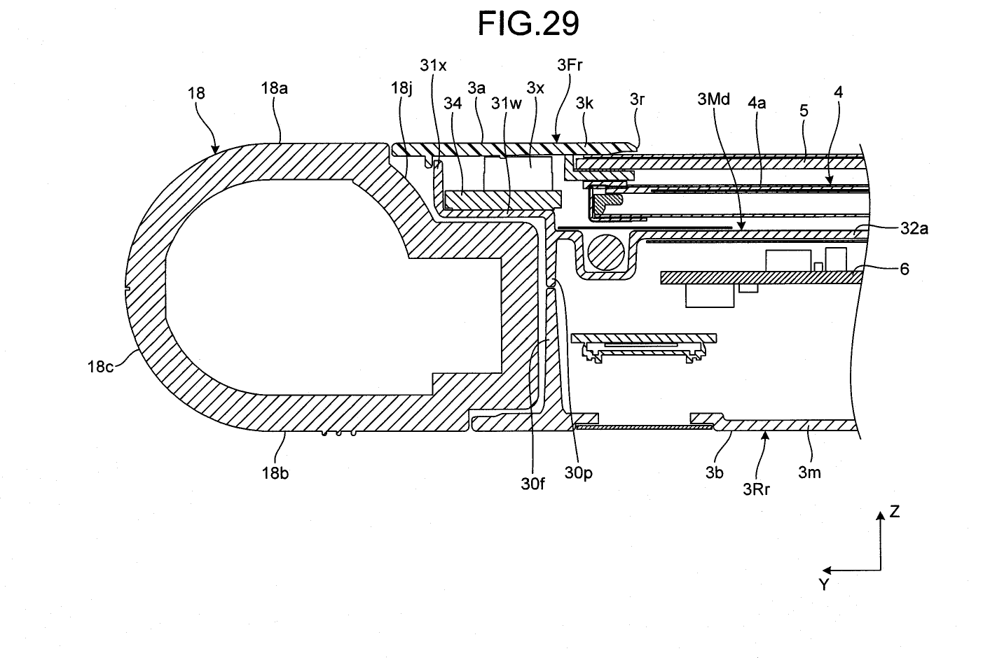

The third member 3Md also comprises wall portions (protrusions, supports) 31w and 31x for supporting a board 34 having a camera (electronic component, component) 3x, as illustrated in FIG. 29. The board 34 is arranged in an orientation along the end 3c of the housing 3 and along the wall portion 3k of the housing 3, and facing the wall portion 3k. The wall portion 31w protrudes from an end of the wall portion 32a. The wall portion 31x is bent at the edge of the wall portion 31w, and extends toward the wall portion 3k. The board 34 is enclosed in an area surrounded by the wall portion 3k, the wall portion 31x, and the wall portion 31w. The wall portion 31w, the wall portion 31x, the camera 3x, and the board 34 projects into a space formed by the recessed portion 18j formed on the battery 18. In the embodiment, as an example, the board 34 can be supported on the perimeter of the third member 3Md using the third member 3Md. Therefore, according to the embodiment, as an example, an area (space) formed between the housing 3 and the battery 18 can be more effectively used.

As described above, in the embodiment, as an example, the wall portion 30p of the third member 3Md is covered by the battery 18 at the end 3c of the housing 3, and the battery 18 is supported by the wall portion 30p. Therefore, according to the embodiment, as an example, the third member 3Md can be used for supporting a module such as the battery 18. Furthermore, as an example, because the third member 3Md is covered by the battery 18, a process for improving the appearance, such as painting, can be omitted for the third member 3Md.

Furthermore, in the embodiment, as an example, the screws 10 that are couplers for coupling the first member 3Fr and at least one of the second member 3Rr and the third member 3Md are covered by the battery 18. Therefore, according to the embodiment, as an example, the first member 3Fr and at least one of the second member 3Rr and the third member 3Md can be coupled more securely, while avoiding inconvenience caused by the couplers being exposed.

Furthermore, in the embodiment, as an example, the screws 10 that are couplers coupling the second member 3Rr and the third member 3Md and being covered by the first member 3Fr are provided. Therefore, according to the embodiment, as an example, the second member 3Rr and the third member 3Md can be coupled more securely, while suppressing inconvenience caused by the couplers being exposed.

Furthermore, in the embodiment, as an example, the first member 3Fr is coupled to at least one of the second member 3Rr and the third member 3Md at some points along the ends 3d, 3e, and 3f in a manner being covered by at least one of the second member 3Rr and the third member 3Md. Therefore, according to the embodiment, as an example, inconvenience caused by the coupling between the first member 3Fr and at least one of the second member 3Rr and the third member 3Md being exposed can be suppressed.

Furthermore, in the embodiment, as an example, the coupled portions 30e of the first member 3Fr are coupled to the coupled portions (in the embodiment, the coupled portions 30h, as an example) comprised at least one of the second member 3Rr and the third member 3Md at some points along the ends 3d, 3e, and 3f. Therefore, according to the embodiment, as an example, no couplers such as the screws 10 is used at these points along the ends 3d, 3e, and 3f in coupling the first member 3Fr to at least one of the second member 3Rr and the third member 3Md. In this manner, the structure can be further simplified.

Furthermore, in the embodiment, as an example, the third member 3Md comprises the wall portion 32a covering the rear surface 4b of the display device 4, and the wall portion 30r covering the side surface 4c extending between the display screen 4a and the rear surface 4b of the display device 4. Therefore, according to the embodiment, as an example, the third member 3Md can better support the display device 4 more reliably.

Furthermore, in the embodiment, as an example, the wall portion 32a of the third member 3Md comprises the openings 31y. Therefore, according to the embodiment, as an example, the third member 3Md can be structured more light-weighted. In addition, as an example, ventilation in the housing 3 can be better improved.

Furthermore, in the embodiment, as an example, the openings 31y are formed at positions offset from or disposed away from the board 6. Therefore, according to the embodiment, as an example, the air collected from the openings 31y can be better prevented from flowing against the board 6 and not reaching the rear side of the board 6.

Furthermore, in the embodiment, as an example, the first member 3Fr is made of a synthetic resin material, and the second member 3Rr and the third member 3Md are made of metallic materials. Therefore, according to the embodiment, as an example, functions can be distributed among these members, and structural and manufacturing advantages can be better achieved.

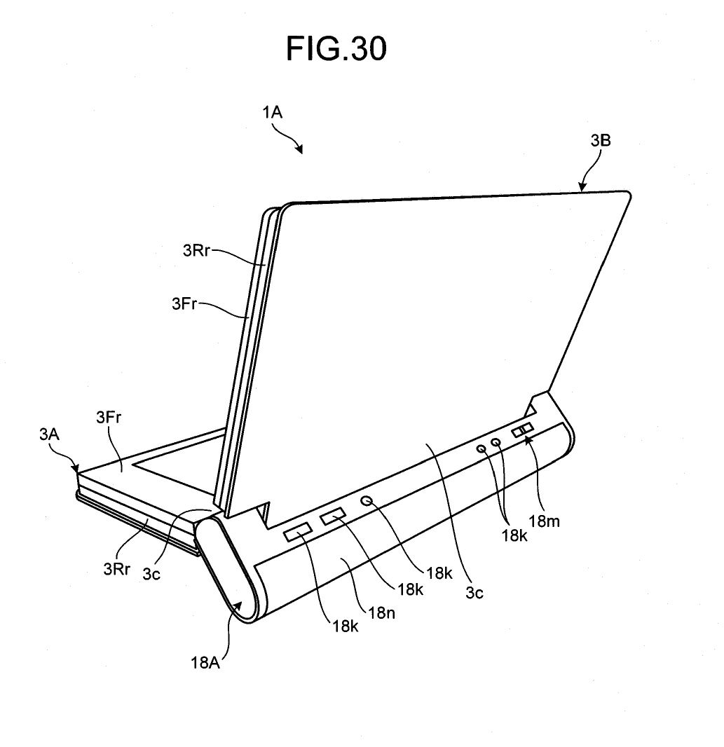

While the embodiment has been described above, the embodiment has been presented by way of an example only. The embodiments are not limited thereto, and various modifications are still possible. For example, the end 3c may be covered by a hinge unit 18A that is not a module such as a battery but is a functional component, like in an electronic device 1A illustrated in FIG. 30 and having two housing 3A and 3B connected to each other in a rotatable manner via the hinge unit 18A. Such a structure also can achieve the same advantageous effects. The hinge unit 18A may comprise a connector 18k, a switch (operating module) 18m, and a battery 18n. Furthermore, the technical characteristics of each of the embodiments may be implemented in a manner combined as appropriate. Furthermore, the specifications of each element (e.g., structure, type, direction, form, size, length, width, thickness, height, number, arrangement, position, and material) can be changed and realized as appropriate.

Moreover, the various modules of the systems described herein can be implemented as software applications, hardware and/or software modules, or components on one or more computers, such as servers. While the various modules are illustrated separately, they may share some or all of the same underlying logic or code.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A television receiver comprising:
a display comprising a display screen;
a first housing member configured to cover an edge of the display screen;
a second housing member at a first side of the display opposite a second side of the display where the display screen is disposed, the second housing member being configured to cover a rear surface of the display;
a third housing member between the second housing member and the display, the third housing member being configured to support the display and comprising a side wall extending between the first housing member and the second housing member and an end portion, wherein the end portion is located on an opposite side of the side wall and covered by at least one of the first housing member and the second housing member;
a circuit board between the second housing member and the display;
a connector electrically connected to the circuit board and exposed to an outside of the side wall of the third housing member; and
a module attached to the third housing member where the module covers the side wall, and electrically connected to the connector.

2. The television receiver of claim 1, further comprising a coupler configured to couple the first housing member and at least one of the second housing member and the third housing member, and to be covered by the module.

3. The television receiver of claim 1, further comprising a second coupler configured to couple the second housing member and the third housing member, and to be covered by the first housing member.

4. The television receiver of claim 1, wherein the first housing member is configured to be coupled with at least one of the second housing member and the third housing member while being covered by at least one of the second housing member and the third housing member along the end portion.

5. The television receiver of claim 4, wherein
the first housing member comprises a first engaged portion disposed along the end portion, and
a member coupled to the first housing member comprises a second engaged portion configured to be engaged with the first engaged portion.

6. The television receiver of claim 1, wherein the third housing member further comprises a first wall portion configured to cover the rear surface of the display, and a second wall portion configured to cover a side surface extending between the display screen and the rear surface of the display.

7. The television receiver of claim 6, wherein the first wall portion comprises an opening.

8. The television receiver of claim 7, wherein the opening is disposed away from the circuit board.

9. The television receiver of claim 1, wherein the first housing member is made of a synthetic resin material, and the second housing member and the third housing member are made of metallic materials.

10. An electronic device comprising:
an electronic component;
a first member configured to cover at least a part of the electronic component;
a second member at a first side of the electronic component opposite a second side of the electronic component where the first member is disposed; and
a third member between the second member and the electronic component, the third member being configured to support the electronic component and comprising a first end portion covered by a component that is partially exposed and a second end portion covered by at least one of the first member and the second member.
